(19) United States
(12) Patent Application Publication
(10) Pub. No.: US 2011/0076456 A1
(43) Pub. Date: Mar. 31, 2011

(54) LENS ARRAYS AND METHODS OF MAKING THE SAME

(75) Inventor: Jian Jim Wang, Orefield, PA (US)

(73) Assignee: Abraxis Bioscience LLC, Los Angeles, CA (US)

(21) Appl. No.: 12/851,078

(22) Filed: Aug. 5, 2010

Related U.S. Application Data
(63) Continuation of application No. 11/598,494, filed on Nov. 13, 2006, now abandoned.
(60) Provisional application No. 60/800,080, filed on May 12, 2006.

(51) Int. Cl. G02B 1/10; C23C 16/44; C23C 16/02; C23C 16/04; B32B 3/26; B32B 9/00

(52) U.S. Cl. 428/164; 427/162; 216/26; 428/161

(57) ABSTRACT

In general, in a first aspect, the invention features a method that includes depositing a first material on a surface of an article to form a layer including the first material. The surface of the article includes a plurality of protrusions and the layer including the first material forms a plurality of lenses. Each lens corresponds to a protrusion on the substrate surface.

### CROSS-REFERENCE TO RELATED APPLICATIONS

This application claims priority to Provisional Patent Application No. 60/800,080, entitled “LENS ARRAYS AND METHODS OF MAKING THE SAME,” filed on May 12, 2006, the entire contents of which are incorporated herein by reference.

### TECHNICAL FIELD

This disclosure relates to lens arrays and methods for making lens arrays.

### BACKGROUND

Multiple lenses can be arranged to form a lens array. In certain embodiments, lens arrays are made by forming multiple lenses on a common substrate, providing an integrated array of lenses.

### SUMMARY

In general, in a first aspect, the invention features a method that includes depositing a first material on a surface of an article to form a layer including the first material. The surface of the article includes a plurality of protrusions and the layer including the first material forms a plurality of lenses. Each lens corresponds to a protrusion on the substrate surface.

Embodiments of the method can include one or more of the following features. For example, depositing the first material can include sequentially depositing a plurality of layers of the first material where one of the layers of the first material is deposited on the surface of the article. Depositing the plurality of layers of the first material can include depositing a layer of a precursor and exposing the layer of the precursor to a reagent to provide a layer of the first material. The reagent can chemically reacts with the precursor to form the first material. For example, the reagent can oxidize the precursor to form the first material. In some embodiments, depositing the layer of the precursor includes introducing a first gas comprising the precursor into a chamber housing the article. Exposing the layer of the precursor to the reagent can include introducing a second gas comprising the reagent into the chamber. A third gas can be introduced into the chamber after the first gas is introduced and prior to introducing the second gas. The third gas can be inert with respect to the precursor. The third gas can include at least one gas selected from the group consisting of helium, argon, nitrogen, neon, krypton, and xenon. The precursor can be selected from the group consisting of tris(tert-butoxy)silanol, (CH₃)₃Al, TiCl₄, SiCl₄, SiH₂Cl₂, TaCl₃, AlCl₃, Hf-ethaoxide and Ta-ethaoxide. Forming the layer including the first material further can include depositing a second material by sequentially depositing a plurality of layers of the second material, one of the layers of the second material being deposited on the first material, wherein the second material is different from the first material. In certain embodiments, the plurality of layers of the first material are monolayers of the first material.

The first material can be deposited using atomic layer deposition. The first material can be a dielectric material. In some embodiments, the first material is an oxide. For example, the oxide can be selected from the group consisting of SiO₂, Al₂O₃, Nb₂O₅, TiO₂, ZrO₂, HfO₂ and Ta₂O₅.

The layer including the first material can be formed by depositing one or more additional materials on the article, where the one or more additional materials are different from the first material.

The layer including the first material can be formed from a nanolaminate material that includes the first material.

In some embodiments, the protrusions are formed in a layer comprising a substrate material, where the first material and the substrate material are the same. The protrusions can be formed from a second material, where the first material and the second material are different.

The method can include forming the protrusions in a surface of the article prior to depositing the first material. The article can include a substrate material and forming the protrusions comprises etching the substrate material. In some embodiments, the article includes a substrate and forming the protrusions comprises depositing a layer of a second material on a surface of a substrate. Forming the protrusions can include forming a layer of a resist on a base layer and transferring a pattern to the layer of the resist, where the pattern corresponds to an arrangement of the protrusions. The pattern can be transferred to the resist using a lithographic technique. For example, the pattern can be transferred to the resist using photolithography or using imprint lithography.

The protrusions can be periodically arranged on the article surface. The arrangement of protrusions can have a period of about 1 μm or more (e.g., about 3 μm or more) in at least one direction. The arrangement of protrusions can have a period of about 30 μm or less (about 20 μm or less) in at least one direction. At least some of the plurality of lenses can have a radius of curvature in a first plane of about 10 μm or less.

In some embodiments, at least two of the lenses are different sizes. In certain embodiments, each of the lenses in the plurality of lenses is substantially the same size as the other lenses in the plurality of lenses.

The plurality of lenses can form a lens array. The lenses can be cylindrical lenses. The protrusions can be ridges that extend along a first direction in a plane of the article.

In general, in another aspect, the invention features a method that includes using atomic layer deposition to form a plurality of lenses on a surface of an article. Embodiments of the methods can include one or more of the features of other aspects.

In general, in a further aspect, the invention features a method that includes forming a layer including a first material by sequentially depositing a plurality of monolayers of the first material, one of the monolayers of the first material being deposited on a first surface of an article. The layer including the first material comprises a plurality of lenses. Embodiments of the methods can include one or more of the features of other aspects.

In general, in another aspect, the invention features an article that includes an object having a surface including a plurality of protrusion, where the protrusions include a first material, and a layer of a second material supported by the object, the second material being different from the first material. The layer of the second material includes a plurality of lenses and each lens corresponds to one of the protrusions. Embodiments of the article can be formed using the methods of other aspects and can include one or more of the features mentioned in connection with the other aspects.

In another aspect, the invention features a device that includes a plurality of detectors and the article of the aforementioned aspect. Each of the lenses in the article corresponds to a detector of the plurality of detectors.

Embodiments can include one or more of the following advantages.

Lens arrays can be economically formed using the methods disclosed herein. For example, lens arrays can be formed on a large scale using combinations of conventional processes and inexpensive (e.g., commodity) materials.

The methods disclosed offer substantial versatility in lens array design. For example, the methods provide a maker the ability to accurately control the size, shape, and layout of lenses in the lens arrays. One or two dimensional arrays can be formed. Lenses can be spherical or aspherical. The radius of curvature of lenses can also be varied.

The methods can offer versatility in the optical properties of materials used to form the lenses. For example, the lenses can be formed from composite materials where the relative ratio of different component materials of the composite is selected to provide a desired refractive index of the composite material. Furthermore, the methods allow one to form composite materials with a varying refractive index profile, providing, for example, lenses formed from graded index materials.

Lens arrays having small lens elements can be formed. For example, arrays of lenses having lateral dimensions of about 5 μm or less can be formed. In some embodiments, arrays of lenses having lateral dimensions about 0.5 μm or less (e.g., about 0.1 μm or less) can be formed.

Embodiments include robust lens arrays. For example, lens arrays can be formed exclusively from inorganic materials, such as inorganic glasses, which may be resistant to a number of environmental hazards the lens arrays might encounter during use. The inorganic materials can be resistant to water and/or organic solvents. The inorganic materials can have relatively high melting temperatures (e.g., about 300° C. or more), allowing lens arrays to be exposed to high temperatures without significantly deteriorating their optical performance.

Embodiments include lens arrays that can be used in the ultraviolet (UV) portion of the electromagnetic spectrum without substantial degradation of the materials forming the lens array. For example, as mentioned above, lens arrays can be formed entirely form inorganic materials, such as inorganic glasses, which are more stable than many organic materials when exposed to UV radiation.

In some embodiments, the lens arrays are mechanically flexible. For example, lens arrays can be formed on flexible substrates, such as polymer substrates.

Lens arrays can be advantageously used in a number of applications. For example, in certain applications, lens arrays can be used to improve the light collection efficiency of detector arrays. In some embodiments, lens arrays are used to provide detector arrays with small detector elements and high light collection efficiency. Such detector arrays can be used in high resolution detector arrays.

In some applications, lens arrays can be used to improve efficiency in flat panel displays. For example, lens arrays can be used to improve the extraction efficiency of emissive displays, such as organic light emitting diode (OLED) displays. Lens arrays can also be used to improve the transmission efficiency of transmission displays, such as transmissive liquid crystal displays.

Lens arrays can also be used to provide desirable illumination (e.g., collimated light with substantially uniform intensity profile) of light modulators in projection displays.

The details of one or more embodiments of the invention are set forth in the accompanying drawings and the description below. Other features and advantages will be apparent from the description, drawings, and claims.

### DESCRIPTION OF DRAWINGS

FIG. 1A is a cross-sectional view of a portion of an embodiment of a lens array.

FIG. 1B is a cross-sectional view of a lens in the lens array shown in FIG. 1A.

FIGS. 1C-1F are cross-sectional views of four different lenses.

FIG. 2A is a cross-sectional view of an embodiment of a lens.

FIG. 2B is a cross-sectional view of an embodiment of a lens.

FIG. 3A is a cross-sectional view of a portion of an embodiment of a lens array.

FIGS. 3B-D are plan views of embodiments of lens arrays.

FIGS. 42A-4I show steps in the manufacture of an embodiment in a lens array.

FIG. 5 is a schematic diagram of an embodiment of an atomic layer deposition system.

FIG. 6 is a flow chart showing steps for forming a nanolaminate using atomic layer deposition.

FIG. 7A is a cross-sectional view of an embodiment of a sensor array.

FIG. 7B is a cross-sectional view of an embodiment of a flat panel display.

FIG. 8 is a schematic diagram of an embodiment of an illumination system.

FIGS. 9A and 9B are scanning electron micrographs of a seed layer and a corresponding lens array, respectively.

FIGS. 10A and 10B are scanning electron micrographs of a lens array.

FIG. 11 is a plot of the transmission spectrum of the lens array shown in FIGS. 10A and 10B.

Like reference symbols in the various drawings indicate like elements.

### DETAILED DESCRIPTION

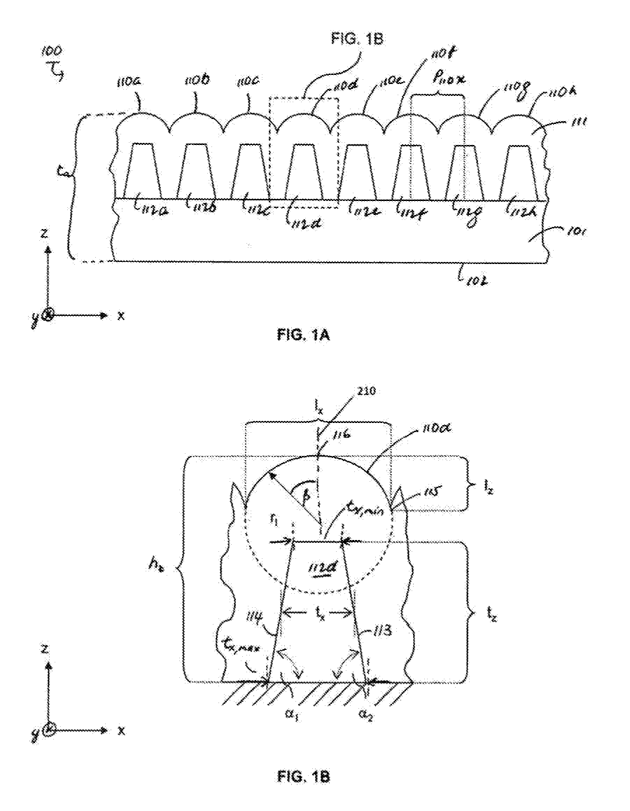

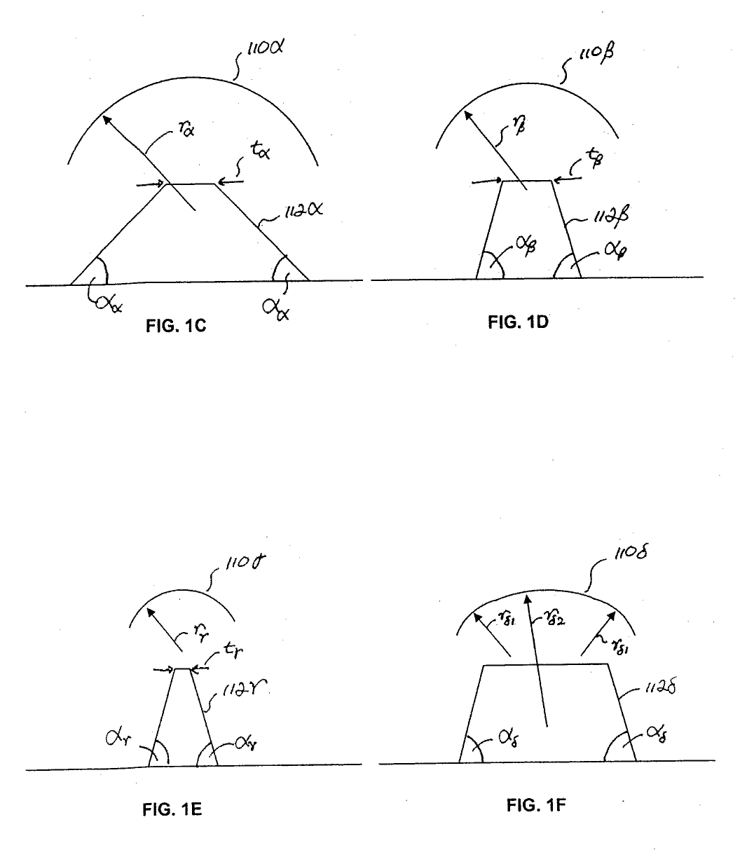

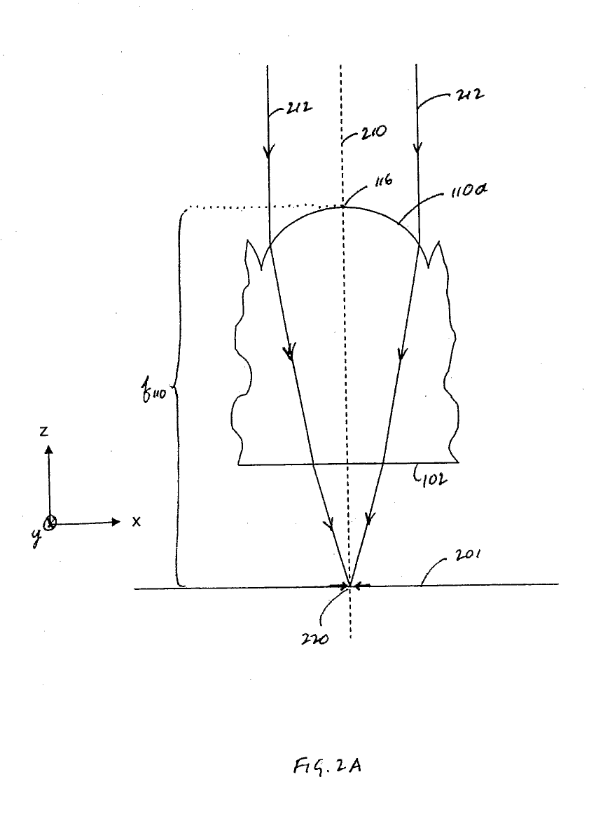

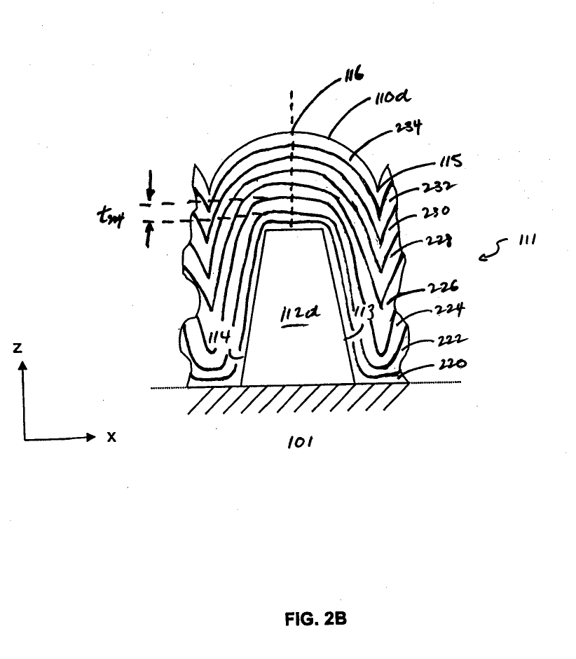

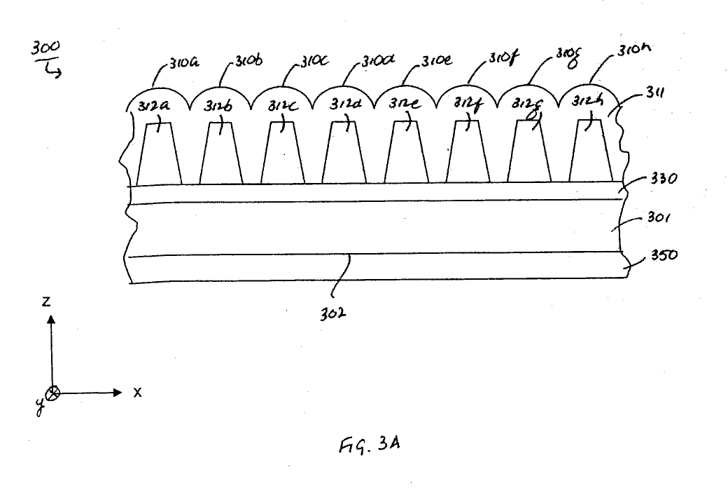

Referring to FIGS. 1A and 1B and FIG. 2A, a lens array 100 includes a number of lenses 110a-110h formed in a surface of a lens layer 111. Lens array 100 also includes a substrate 101, which supports lens layer 111. Substrate 101 also supports a number of protrusions 112a-112h. Each protrusion 112a-112h corresponds to a lens 110a-110h, respectively, in lens array 100. As discussed below, in certain embodiments, lenses 110a-110h are formed by depositing material onto protrusions 112a-112h to form lens layer 111. Lenses 110a-110h are protrusions of the surface of layer 111 that correspond to protrusions 112a-112h. It is believed that the size and shape of lenses 110a-110h are thus related to the size and shape of protrusions 112a-112h and the amount of material deposited onto protrusions 112a-112h. Accordingly, lenses of varying size and shape can be prepared by forming protrusions of varying dimension and with varying the amount of material deposited onto the protrusions.

FIGS. 1A and 1B also show a Cartesian coordinate system, which is referred to in the description of lens array 100. FIGS. 1A and 1B show a portion of lens array 100 in cross-section through the x-z plane. The cross-section of lens array 100 through the y-z plane is substantially the same as the cross-section through the x-z plane.

While only eight lenses are shown in lens array 100 in FIG. 1A, in general, lens arrays can include fewer or more lenses. In some embodiments, lens arrays include tens or hundreds of lenses. In certain embodiments, lens arrays includes hundreds of thousands to millions of lenses. The number of lenses, and their arrangement in the array, are generally determined based on the application of the lens array. Arrangements of lenses in lens arrays and applications of lens arrays are discussed below.

In general, the dimensions of lens array 100 along the x-, y-, and z-axes can vary as desired. Along the z-axis, lens array 100 has a thickness tₐ. In some embodiments, tₐ can be relatively small. For example, tₐ can be about 1 mm or less (e.g., about 0.5 mm or less, about 0.4 mm or less, about 0.3 mm or less, about 0.2 mm or less, about 0.1 mm or less).

In certain embodiments, lens array 100 extends substantially further in the x- and/or y-directions than it does in the z-direction. For example, lens array 100 can extend for about 1 cm or more (e.g., about 2 cm or more, about 3 cm or more, about 5 cm or more, about 10 cm or more) in the x- and/or y-directions, while tₐ is about 1 mm or less.

Each lens 110a-110h focuses incident light at a wavelength λ propagating parallel to the z-axis to a waist. Here, λ is referred to as the operational wavelength lens array 100. In general, λ can vary depending on the specific application for which lens array 100 is intended. In some embodiments, λ is in the visible portion of the electromagnetic spectrum (e.g., in a range from about 400 nm to about 700 nm). In certain embodiments, λ is in the IR portion of the electromagnetic spectrum (e.g., in a range from about 700 nm to about 2,000 nm). In some embodiments, λ is in the UV portion of the electromagnetic spectrum (e.g., in a range from about 100 nm to about 400 nm).

In some embodiments, lens array 100 can focus light at multiple wavelengths to a waist. In some embodiments, lens array 100 can focus a band of wavelengths, including λ, to a waist. In some embodiments, lens array 100 can focus light for a portion or all of the visible portion of the electromagnetic spectrum to a waist.

Referring specifically to FIG. 1B, each lens is characterized by a first and second lateral dimension, lₓ and l_{y}, where only lₓ is shown in FIG. 1B. l_{y} is the lateral dimension of lens 110d along the y-direction. In general, lₓ can be the same as or different than l_{y}. In some embodiments, lₓ and/or l_{y} is about 100 μm or less (e.g., about 80 μm or less, about 70 μm or less, about 60 μm or less, about 50 μm or less, about 40 μm or less, about 30 μm or less, about 20 μm or less, about 10 μm or less, about 5 μm or less, about 3 μm or less, about 2 μm or less, about 1 μm or less, about 0.5 μm or less, about 0.3 μm or less, about 0.2 μm or less).

Each lens also has a vertical dimension, l_{Z}, which refers to the dimension of the lens along the z-axis from a base 115 between adjacent lenses and the vertex 116 of the lens. A lens axis, 210, intersects lens 110d at vertex 116. Lens axis 118 is parallel to the z-axis. In certain embodiments, l_{z} is about 50 μm or less (e.g., about 40 μm or less, about 30 μm or less, about 20 μm or less, about 10 μm or less, about 5 μm or less, about 3 μm or less, about 2 μm or less, about 1 μm or less, about 0.5 μm or less, about 0.3 μm or less, about 0.2 μm or less).

Each lens is also characterized by a radius of curvature, r₁, which, for each point on the lens surface, refers the radius of the osculating circle at that point. In embodiments where lens 110d is a spherical lens, r₁ is substantially constant over the surface of the lens. Alternatively, where lens 110d is aspherical, r₁ varies over the lens surface. In some embodiments, lens 110d is a rotationally-symmetrical aspherical lens, in which case lens 110d is continuously rotationally symmetric with respect to lens axis 118, but r₁ varies for varying β. In some embodiments, r₁ is about 100 μm or less (e.g., about 80 μm or less, about 70 μm or less, about 60 μm or less, about 50 μm or less, about 40 μm or less, about 30 μm or less, about 20 μm or less, about 10 μm or less, about 8 μm or less, about 5 μm or less, about 4 μm or less, about 3 μm or less, about 2 μm or less, about 1 μm or less, about 0.5 μm or less, about 0.3 μm or less, about 0.2 μm or less)

Each lens is further characterized by a thickness, h_{z}, which refers to the dimension of layer 111 from the surface of substrate 101 to vertex 116 measured along the z-axis. In certain embodiments, h_{z} is in a range from about 500 nm (e.g., about 1 μm or more, about 2 μm or more, about 5 μm or more, about 10 μm or more) to about 100 μm (e.g., about 80 μm or less, about 50 μm or less, about 30 μm or less).

Lenses 110a-110h are periodically spaced in both the x-direction and the y-direction. The spatial period, P₁₁₀ₓ of the lenses in the x-direction is shown for adjacent lenses 110f and 110g in FIG. 1A. Lens array 100 has a corresponding period, P_{110y}, in the y-direction. In general, P₁₁₀ₓ can be the same as or different than P_{110y}. P₁₁₀ₓ is typically the same as or more than lₓ and P_{110y} is typically the same as or more than l_{y}. In some embodiments, P₁₁₀ₓ and/or P_{110y} are in a range from about 100 nm to about 100 μm. For example, P₁₁₀ₓ and/or P_{110y} can be about 200 nm or more (e.g., about 500 nm or more, about 800 nm or more, about 1 μm or more, about 2 μm or more, about 5 μm or more, about 10 μm or more, about 20 μm or more). P₁₁₀ₓ and/or P_{110y} can be about 80 μm or less (e.g., about 60 μm or less, about 50 μm or less, about 40 μm or less, about 30 μm or less).

Typically, substrate 101 is sufficiently thick to provide sufficient mechanical support for lens layer 111. Here, substrate thickness refers to the dimension of the substrate along the x-axis. In some embodiments, substrate 101 has a thickness of about 1 mm or less (e.g., about 800 μm or less, about 500 μm or less, about 300 μm or less). In some embodiments, substrate 101 has a thickness in a range from about 100 μm or about 300 μm.

In general, the size and shape of protrusions 112a-112h can vary depending on the desired size and shape of lenses 110a-110h. The relationship between the size and shape of protrusions 112a-112h and the size and shape of lenses 110a-110h are discussed below.

Protrusions 112a-112h have a trapezoidal cross-sectional shape. Referring specifically to FIG. 1B, the trapezoid is characterized by a height, t_{z}, a base width, t_{x, max}/a peak width, t_{x, min}, and base angles α₁ and α₂. The trapezoid is also characterized by a width, tₓ, which refers to the dimension of the trapezoid along the x-axis measured at half of t_{z}.

Height, t_{z}, is the dimension of protrusion 112d from the surface of substrate 101 to the protrusion's peak, measured along the z-axis. In certain embodiments, t_{z} is in a range from about 100 nm to about 100 μm. For example, t_{z} can be about 500 nm or more (e.g., about 1 μm or more, about 2 μm or more, about 5 μm or more, about 10 μm or more). t_{z} can be about 80 μm or less (e.g., about 50 μm or less, about 20 μm or less).

Base width, t_{x, max}, refers to the dimension of protrusion 112d along the x-direction at the surface of substrate 101. In certain embodiments, t_{x, max} is about 20 μm or less (e.g., about 15 μm or less, about 10 μm or less, about 8 μm or less, about 5 μm or less, about 4 μm or less, about 3 μm or less, about 2 μm or less, about 1 μm or less, about 800 nm or less, about 500 nm or less).

Peak width, t_{x, min}, refers to the dimension of protrusion 112d along the x-direction at the peak of the protrusion. Typically, t_{x, min} is less than t_{x, max}. In certain embodiments, t_{x, min} is about 20 μm or less (e.g., about 15 μm or less, about 10 μm or less, about 8 μM or less, about 5 μm or less, about 4 μm or less, about 3 μm or less, about 2 μm or less, about 1 μm or less, about 800 nm or less, about 500 nm or less).

Base angles α₁ and α₂ refer to the angles the opposing side walls 114 and 113 of protrusion 112d make with respect to surface of substrate 101. Generally, α₁ can be the same as or different than α₂. α₁ and/or α₂ can be about 10° or more (e.g., about 20° or more, about 30° or more, about 40° or more, about 50° or more, about 60° or more, about 70° or more, about 80° or more). α₁ and α₂ are less than 90.

tₓ is generally less than t_{x, max} and more than t_{x, min}. In some embodiments, tₓ is about 20 μm or less (e.g., about 15 μm or less, about 10 μm or less, about 8 μm or less, about 5 μm or less, about 4 μm or less, about 3 μm or less, about 2 μm or less, about 1 μm or less, about 800 nm or less, about 500 nm or less).

Protrusions 112a-112h are periodically spaced with a period that is substantially the same as the spacing of lenses 110a-110h.

As mentioned previously, in certain embodiments, lenses 110a-110h are formed by depositing material onto protrusions 112a-112h, where the material forms lens layer 111. The protrusions cause undulations to form in the surface of the layer of deposited material. The undulations define lenses 110a-110h. In such embodiments, the size and shape of the protrusions affects the size and shape of the lenses. Accordingly, the size and shape of the lenses can be varied by varying the size and shape of the protrusions.

For example, the radius of curvature of lens 110d can vary depending on the base angles α₁ and α₂. Referring to FIGS. 1C and 1D, for example, protrusions 112α and 112β have the same height and the same peak width. However, protrusion 112α has base angles α_{α} that are smaller than base angles α_{β} of protrusion 112β. As a result, a lens 110α formed over protrusion 112α has a radius of curvature, r_{α}, that is larger than a radius of curvature, r_{β}, of a lens 110_{β} formed over protrusion 112_{β}.

The radius of curvature of the lens can also depend on the peak width of the protrusions. For example, referring also to FIG. 1E, a protrusion 112γ has the same height as protrusions 112α and 112β, and has base angles α_{γ} equal to α_{β}. However, protrusion 112_{γ} has a smaller peak width, t_{γ}, than t_{β}. As a result, the radius of curvature, r_{γ}, of lens 110γ corresponding to protrusion 112γ is smaller than r_{β}.

Protrusion shape can also be selected to provide aspherical lenses. For example, referring also to FIG. 1F, a protrusion 112δ has the same height as protrusion 112γ. Furthermore, protrusion 112δ has base angles α_{δ} equal to α_{γ}. However, the peak with of protrusion 112δ is larger than the peak with of protrusion 112γ. As a result, the radius of curvature of a lens 110δ formed over protrusion 112δ varies depending on the proximity of the portion of the lens to the vertices of protrusion 112δ. In particular, portions of lens 110δ close to the vertices of protrusion 112δ have a radius of curvature, r_{δ1}, that is smaller than the radius of curvature, r_{δ2}, of lens 110δ further from the protrusion's vertices. The larger radius of curvature, r_{δ2}, corresponds to the flat peak of protrusion 112δ.

The shape of lenses can also vary depending on the amount of material deposited over the protrusions, the type of material, the methods used to deposit the materials, as well as the conditions under which the material is deposited. Types of materials and deposition methods are discussed below.

Referring again to FIG. 1B, protrusion 112d is depicted as having a perfectly trapezoidal cross-sectional shape. However, in general, the cross-sectional shape of a protrusion may deviate slightly being a perfect trapezoid, due to, for example, limited precision of the processes used to fabricate the protrusions. Nevertheless, protrusions including such deviations are considered to have trapezoidal cross-sectional shapes.

Furthermore, while the protrusions in lens array 100 have a trapezoidal cross-sectional shape, in general, the shape of the protrusions can vary. For example, in some embodiments, protrusions can have a rectangular cross-sectional shape or a triangular cross-sectional shape. In some embodiments, the protrusions can have rotational symmetry. For example, the protrusions can be conical or cylindrical in shape. In some embodiments, the protrusions are pyramidal in shape (e.g., three or four-sided pyramids). In certain embodiments, the protrusions are rectangular in shape. The shape of the protrusions can be controlled by the etching process. For example, by varying reactive ion etching conditions, one can vary the base angles of the protrusions with a trapezoidal cross-section.

Focusing by a lens is illustrated in FIG. 2A, which shows lens 110d. Rays 212 of light at λ incident on lens 110d are refracted at the lens surface and again when exiting substrate 101 at surface. As a result, rays 212 focus to a waist 220 at a focal plane 201 of lens 110d. In embodiments where lens array 100 operates at multiple wavelengths, different wavelengths can focus to a corresponding waist at different planes, defining a focal region.

The diameter of the focused light at waist 220 refers to the diameter of a circular area in focal plane 201 centered on lens axis 210 through which 90% of the beam intensity at λ passes. Waist 220 can have a diameter of about 10λ or less (e.g., about 8λ or less, about 5λ or less, about 4λ or less, about 3λ or less, about 2λ or less). In some embodiments, waist 220 can be about 5 μm or less (e.g., about 4 μm or less, about 3 μm or less, about 2 μm or less, about 1 μm or less, about 800 nm or less, about 500 nm or less).

Focal plane 201 is located a distance f₁₁₀ from a vertex of lens 116, which is where lens 110d intersects lens axis 210. In general, f₁₁₀ varies depending on the radius of curvature of the lens and the refractive index of the materials used to form lens array 100. In some embodiments, f₁₁₀ is larger than the thickness of substrate 101 and h_{z} combined, so that the focal plane is accessible for positioning other optical components thereat. f₁₁₀ can be about 50 μm or more (e.g., about 100 μm or more, about 200 μm or more, about 300 μm or more, about 400 μm or more, about 500 μm or more, about 1 μm or more, about 2 μm or more). Alternatively, in some embodiments, f₁₁₀ can be about 40 μm or less (e.g., about 30 μm or less, about 20 μm or less, about 10 μm or less, about 5 μm or less, about 1 μm or less). (Typically the small lens has very short focus lens). In general, f₁₁₀ can be less than about 10 mm (e.g., about 8 mm or less, about 5 mm or less, about 3 mm or less).

Turning now to the composition of lens array 100, lens layer 111 and protrusions 112a-112h are formed from materials selected based on a variety of factors, including the materials optical properties, the materials compatibility with the processes used to form lens array 100, and the materials compatibility with the other materials used to form lens array 100. Typically, lens layer 111 and protrusions 112a-112h are formed from optically transmissive materials, including inorganic and/or organic optically transmissive materials. Examples of inorganic materials include inorganic dielectric materials, such as inorganic glasses. Examples of organic optically transmissive materials include optically transmissive polymers. As used herein, optically transmissive materials are materials that, for a 1 mm thick layer, transmit about 50% or more (e.g., about 80% or more, about 90% or more, about 95% or more) normally incident radiation at λ.

In some embodiments, lens layer 111 and/or protrusions 112a-112h include one or more dielectric materials, such as dielectric oxides (e.g., metal oxides), fluorides (e.g., metal fluorides), sulphides, and/or nitrides (e.g., metal nitrides). Examples of oxides include SiO₂, Al₂O₃, Nb₂O₅, TiO₂, ZrO₂, HfO₂, SnO₂, ZnO, ErO₂, Sc₂O₃, and Ta₂O₅. Examples of fluorides include MgF₂. Other examples include ZnS, SiNₓ, SiO_{y}Nₓ, AlN, TiN, and HfN.

In some embodiments, protrusions 112a-112h are formed from an organic material while lens layer 111 is formed from an inorganic material. For example, in certain embodiments, protrusions 112a-112h is formed from a polymer resist (e.g., a photoresist or a resist for nanoimprint lithography), while lens layer 111 is formed from an inorganic glass (e.g., SiO₂ glass).

The composition of lens layer 111 and/or protrusions 112a-112h can be selected to have particular refractive indices at λ. In some embodiments, the refractive index of lens layer 111 is different from the refractive index of protrusions 112a-112h at λ. The different refractive indices between the protrusions and the lens layer can provide refraction of incident light that contributes to the focusing function of the lens array. Alternatively, in certain embodiments, the refractive index of lens layer 111 is the same as the refractive index of protrusions 112a-112h at λ. Matching the refractive index of the protrusions to the lens layer can be advantageous as it reduces (e.g., eliminates) refraction of light and reflection of light at the interface between the lens layer and the protrusions.

In some embodiments, lens layer 111 and/or protrusions 112a-112h are formed from a material that has a relatively high index of refraction, such as TiO₂, which has a refractive index of about 2.35 at 632 nm, or Ta₂O₅, which has a refractive index of 2.15 at 632 nm. Alternatively, lens layer 111 and/or protrusions 112a-112h can be formed from a material that has a relatively low index of refraction. Examples of low index materials include SiO₂ and Al₂O₃, which have refractive indices of 1.45 and 1.65 at 632 nm, respectively.

In some embodiments, the composition of lens layer 111 and/or protrusions 112a-112h have a relatively low absorption at λ, so that lens layer 111 and/or protrusions 112a-112h has a relatively low absorption at λ. For example, lens array 100 can absorb about 5% or less of radiation at λ propagating along axis 101 (e.g., about 3% or less, about 2% or less, about 1% or less, about 0.5% or less, about 0.2% or less, about 0.1% or less).

Lens layer 111 and/or protrusions 112a-112h can include crystalline, semi-crystalline, and/or amorphous portions. Typically, an amorphous material is optically isotropic and may transmit light better than portions that are partially or mostly crystalline. As an example, in some embodiments, both lens layer 111 and protrusions 112a-112h are formed from amorphous materials, such as amorphous dielectric materials (e.g., amorphous TiO₂ or SiO₂). Alternatively, in certain embodiments, protrusions 112a-112h are formed from a crystalline or semi-crystalline material (e.g., crystalline or semi-crystalline Si), while lens layer 111 is formed from an amorphous material (e.g., an amorphous dielectric material, such as TiO₂ or SiO₂).

Lens layer 111 and/or protrusions 112a-112h can be formed from a single material or from multiple different materials. In some embodiments, one or both of lens layer 111 and protrusions 112a-112h are formed from a nanolaminate material, which refers to a composition that is formed of layers of at least two different materials and the layers of at least one of the materials are extremely thin (e.g., between one and about 10 monolayers thick). Optically, nanolaminate materials have a locally homogeneous index of refraction that depends on the refractive index of its constituent materials. Varying the amount of each constituent material can vary the refractive index of a nanolaminate. Examples of nanolaminate portions include portions composed of SiO₂ monolayers and TiO₂ monolayers, SiO₂ monolayers and Ta₂O₅ monolayers, or Al₂O₃ monolayers and TiO₂ monolayers.

Referring to FIG. 2B, an example of a lens array having a lens layer formed from more than one material is shown. In this example, lens layer 111 includes eight sub-layers 220, 222, 224, 226, 228, 230, 232, and 234. Each sub-layer has a thickness, t_{z}, measured along an axis parallel to the z-direction that intersects vertex 116, as illustrated by t₂₂₄ for sub-layer 224. More generally, the number of sub-layers in a lens layer can vary as desired. In some embodiments, a lens layer can include more than eight sub-layers (e.g., about 10 sub-layers or more, about 20 sub-layers of more, about 30 sub-layers or more, about 40 sub-layers or more, about 50 sub-layers or more, about 60 sub-layers or more, about 70 sub-layers or more, about 80 sub-layers or more, about 90 sub-layers or more, about 100 sub-layers or more).

In general, the thickness, t_{z}, and composition for each sub-layer can vary as desired. In some embodiments, the thickness, t_{z}, of each sub-layer in lens layer 111 is about 5 nm or more (e.g., about 10 nm or more, about 20 nm or more, about 30 nm or more, about 50 nm or more, about 70 nm or more, about 100 nm or more, about 150 nm or more, about 200 mm or more, about 300 nm or more).

In some embodiments, the thickness and composition of each sub-layer in lens layer 111 depend on the desired spectral characteristics of lens array 100. For example, the thickness and composition of the sub-layers can be selected so that lens layer 111 performs as an optical filter in addition to focusing light. Optical filters formed form multi-layer films are discussed, for example, in “Thin Film Optical Filters,” 3^{rd} Edition, by H. Angus Macloed, Taylor & Francis, Inc. (2001). Typically, optical filters are formed by multiple alternating layers of relatively high and low refractive index at the wavelength of interest, where the thickness of each sub-layer is less than the wavelength of interest. The difference, Δn, in refractive index between adjacent sub-layers can vary as desired. Δn between each adjacent sub-layer pair can be the same or different. In some embodiments, Δn is about 0.01 or more (e.g., about 0.02 or more, about 0.03 or more, about 0.04 or more, about 0.05 or more, about 0.06 or more, about 0.07 or more, about 0.08 or more, about 0.09 or more, about 0.1 or more, about 0.12 or more, about 0.15 or more, about 0.2 or more, about 0.3 or more, about 0.4 or more, about 0.5 or more).

In general, the optical thickness of each sub-layer can be the same as or different than other sub-layers. The optical thickness refers to the product of the sub-layer's thickness, t_{z}, and the refractive index of the material forming the sub-layer at a wavelength of interest. For example, in embodiments where lens layer 111 is designed to reflect a narrow band of wavelengths (e.g., about 10 nm), the perpendicular optical thickness of each layer can be 0.25λ₀, where λ₀ is the central wavelength in the reflection band. Alternatively, where lens layer 111 is designed to reflect a broad band of wavelengths (e.g., about 100 nm or more, about 150 nm or more, about 200 nm or more), the optical thickness of the sub-layers can vary. For example, different groups of sub-layers in lens layer 111 can have an optical thickness equal to 0.25λᵢ for different wavelengths, λᵢ, within the desired reflection band. In some embodiments, the optical thickness of each sub-layer can be in the range of about 20 nm to about 1,000 nm. For example, the optical thickness of each sub-layer can be about 50 nm or more (e.g., about 100 nm or more, about 150 nm or more, about 200 nm or more, about 250 nm or more, about 300 nm or more). In embodiments, the optical thickness of the sub-layers can be about 800 nm or less (e.g., about 600 nm or less, about 500 nm or less).

In general, the thickness, t_{z}, of each sub-layer in a lens layer can be substantially uniform. For example, the thickness of a given layer can vary by about 5% or less between different portions of a layer (e.g., about 3% or less, about 2% or less, about 1% or less, about 0.5% or less, about 0.1% or less). In some embodiments, the thickness of each sub-layer in a lens layer can vary by about 20 nm or less between different portions of the layer (e.g., about 15 nm or less, about 12 nm or less, about 10 nm or less, about 8 nm or less, about 5 nm or less).

In some embodiments, the thickness of each sub-layer is about 0.25 λ/n where λ is a wavelength to be reflected by the filter and n is the refractive index of the sub-layer. Of course, the thickness of a given sub-layer will vary depending on the refractive index of the material used to form the sub-layer.

The optical transmission characteristics of lens layer 111 can vary depending on a number of design parameters, which include the number of sub-layers in the lens layer, the optical thickness of each sub-layer, the relative optical thickness of different sub-layers, and the refractive index of each sub-layer. In some embodiments, the lens layer can be designed to transmit substantially more light within a band of wavelengths (referred to as a transmission band) impinging on it within a cone of incident angles relative to the z-direction than wavelengths outside the transmission band. For example, the lens layer can transmit about 10 or more times (e.g., about 20 or more times, about 30 or more times, about 40 or more times, about 50 or more times, about 75 or more times, about 100 or more times) more light at wavelengths within the transmission band than wavelengths outside the transmission band.

The wavelengths within the transmission band are referred to as “pass wavelengths,” while the reflected wavelengths are referred to as “block wavelengths.” The width of the transmission band can be relatively broad (e.g., from about 200 nm to about 300 nm or more), or can be narrow (e.g., from about 5 nm to about 40 nm or less). In certain embodiments, the width of the transmission band is from about 40 nm to about 200 nm. In certain embodiments, the lens layer can block (e.g., reflect) substantially all UV (e.g., from about 200 nm to about 380 nm), visible (e.g., from about 380 nm to about 780 nm), and/or IR (e.g., from about 780 nm to about 2,000 nm) wavelengths outside of a transmission band (e.g., all outside the transmission band from about 200 nm to about 2,000 nm). In some embodiments, the lens layer reflects at least about 50% (e.g., about 60% or more, about 80% or more, about 90% or more, about 95% or more, about 98% or more, about 99% or more) of light of at least a wavelength λᵣ incident on the article along the lens axis passing through vertex 116, where λᵣ is in a range from about 200 nm to about 2,000 nm. For example, λᵣ can be about 200 nm, about 300 nm, about 400 nm, about 500 nm, about 600 nm, about 700 nm, about 800 nm, about 900 nm, about 1,000 nm, about 1,100 nm, about 1,200 nm, about 1,300 nm, about 1,400 nm, about 1,500 nm, about 1,600 nm, about 1,700 nm, about 1,900 nm, or about 2,000 nm. In embodiments, the lens layer can reflect at least about 50% (e.g., about 60% or more, about 80% or more, about 90% or more, about 95% or more, about 98% or more, about 99% or more) for multiple wavelengths in a range from about 200 nm to about 2,000 nm, for example, for a band of wavelengths, Δλᵣ, of width 50 nm or more (e.g., about 100 nm or more, about 200 nm or more, about 300 nm or more, about 400 nm or more, about 500 nm or more).

The wavelengths where the spectral characteristics of lens layer transition between the transmission band and the block wavelengths are referred to as the band edge. The position of the band edge corresponds to the wavelength where the transmission of the lens layer for light propagating parallel to the z-axis is 50% of the maximum transmission within the transmission band. In general, the position of the band edge can be selected based on the thickness of the sub-layers in the lens layer. In some embodiments, the lens layer can have a band edge in the region of the spectrum where UV light transitions to visible light. For example, the lens layer can have a band edge at about 350 nm or more (e.g., about 360 nm or more, about 370 nm or more, about 380 nm or more, about 390 nm or more, about 400 nm or more, about 410 nm or more, about 420 nm or more). In certain embodiments, the lens layer can have a band edge in the region of the spectrum where visible light transitions to IR light. For example, the lens layer can have a band edge at about 650 nm or more (e.g., about 660 nm or more, about 670 nm or more, about 680 or more, about 690 nm or more, about 700 nm or more, about 710 nm or more, about 720 nm or more, about 730 nm or more, about 740 nm or more, about 750 nm or more, about 760 nm or more, about 770 nm or more, about 780 nm or more, about 790 nm or more, about 800 nm or more). In some embodiments, lens layer 111 can have high transmission at some or all of the pass wavelengths. For example, transmission at pass wavelengths can be about 80% or more (e.g., about 90% or more, about 95% or more, about 98% or more, about 99% or more).

In general, the transmission at pass wavelengths depends on the absorption and homogeneity of materials used to form the lens layer, and the uniformity and precision of sub-layer thickness. For example, materials with relatively high absorption at pass wavelengths can reduce transmission by absorbing light impinging on the lens layer. Inhomogeneities (e.g., impurities and/or crystalline domains) in the lens layer can reduce transmission by scattering impinging light. Sub-layer thickness discrepancies can result in coherent reflection of impinging light at pass wavelengths, reducing its transmission. Transmission is further improved by reducing reflectance losses at the interfaces between the lens layer and the atmosphere.

Transmission at all or some of the block wavelengths can be relatively low, such as about 5% or less (e.g., about 4% or less, about 3% or less, about 2% or less, about 1% or less). Increasing the lens layer's reflectance and/or absorption at these wavelengths can reduce transmission at block wavelengths. Increasing the number of sub-layers in the lens layer and/or increasing the difference in refractive index between the low index and high index layers can increase reflectance of block wavelengths.

In general, substrate 101 provides mechanical support to lens array 101. In certain embodiments, substrate 101 is transparent to light at wavelength λ, transmitting substantially all light normally incident thereon at wavelength λ (e.g., about 90% or more, about 95% or more, about 97% or more, about 99% or more, about 99.5% or more).

In general, substrate 101 can be formed from any material compatible with the manufacturing processes used to lens array 100 that can support the other layers. In certain embodiments, substrate 101 is formed from a glass, such as BK7 (available from Abrisa Corporation), borosilicate glass (e.g., pyrex available from Corning), aluminosilicate glass (e.g., C1737 available from Corning), or quartz/fused silica. In some embodiments, substrate 101 can be formed from a crystalline material or a crystalline (or semicrystalline) semiconductor (e.g., Si, InP, or GaAs). Substrate 101 can also be formed from an inorganic material, such as a polymer (e.g., a plastic). Examples of polymers include polycarbonate, polymethylmethacrylate, and polyethyleneterepthalate.

In some embodiments, substrate 101 is formed from the same material as protrusions 112a-112h. For example, protrusions 112a-112h can be etched or embossed into a surface of a piece of substrate material, thereby providing a monolithic substrate/protrusion structure.

In certain embodiments, substrate 101 is formed from the same material as lens layer 111. For example, both substrate 101 and lens layer 111 can be formed from the same inorganic glass.

In some embodiments, substrate, 101, protrusions 112a-112h, and lens layer 111 are all formed from the same material.

In some embodiments, lens arrays are formed on substrates that provide further functionality to a device in addition to provide mechanical support for the lens layer and protrusions. For example, as discussed below, in some embodiments, lens arrays can be formed on substrate that include a corresponding array of detectors and/or emitters.

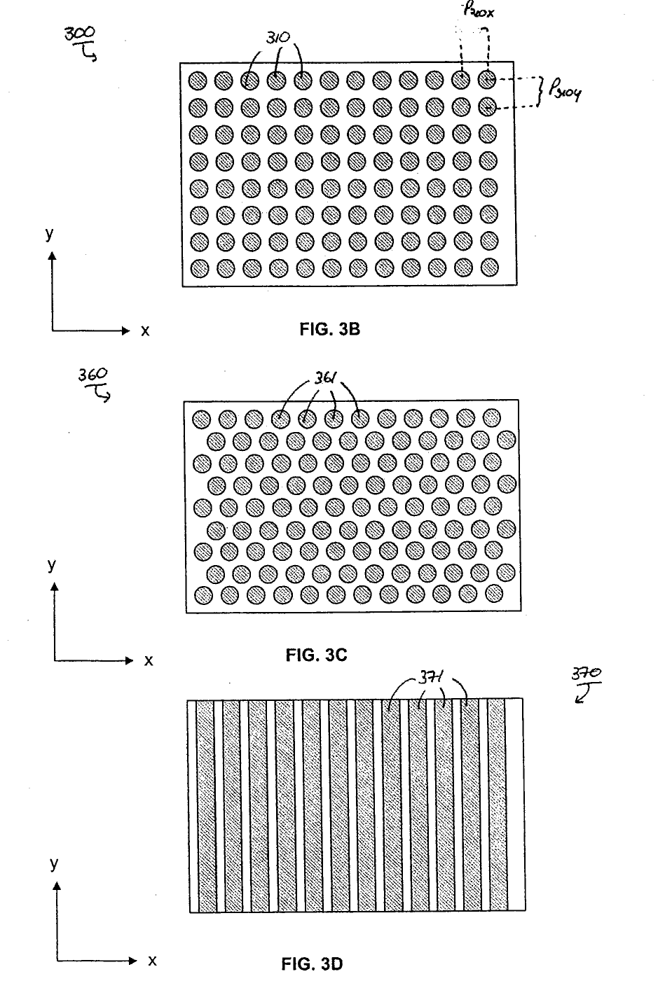

In general, lens arrays can include additional components to those shown for lens array 100. For example, in some embodiments, lens arrays can include additional layers to those shown for lens array 100. Referring to FIG. 3A, for example, a lens array 300 includes an etch stop layer 330 and an antireflection film 350 in addition to substrate 301 and lens layer 311.

Etch stop layer 330 is formed from a material resistant to etching processes used to etch the material(s) from which protrusions 312a-312h are formed (see discussion below). The material(s) forming etch stop layer 330 should also be compatible with substrate 301 and with the materials forming lens layer 311. Examples of materials that can form etch stop layer 330 include HfO₂, SiO₂, Ta₂O₅, TiO₂, SiNₓ, or metals (e.g., Cr, Ti, Ni).

The thickness of etch stop layer 330 can be varied as desired. Typically, etch stop layer 330 is sufficiently thick to prevent significant etching of substrate 101, but should not be so thick as to adversely impact the optical performance of lens array 100. In some embodiments, etch stop layer 330 is about 500 nm or less (e.g., about 250 nm or less, about 100 nm or less, about 75 nm or less, about 50 nm or less, about 40 nm or less, about 30 nm or less, about 20 nm or less).

Antireflection film 350 can reduce the reflectance of light of wavelength λ exiting lens array 300 through surface 302. Antireflection film 350 generally include one or more layers of different refractive index. As an example, antireflection film 350 can be formed from four alternating high and low index layers. The high index layers can be formed from TiO₂ or Ta₂O₅ and the low index layers can be formed from SiO₂ or MgF₂. The antireflection films can be broadband antireflection films or narrowband antireflection films.

In some embodiments, lens array 300 has a reflectance of about 5% or less of light normally incident on lenses 310a-310h at wavelength λ (e.g., about 3% or less, about 2% or less, about 1% or less, about 0.5% or less, about 0.2% or less). Furthermore, lens array 300 can have high transmission of light of wavelength λ. For example, optical retarder can transmit about 95% or more of light propagating parallel to the z-axis impinging thereon at wavelength λ (e.g., about 98% or more, about 99% or more, about 99.5% or more).

In some embodiments, coatings, such as antireflective coatings, can be deposited onto the lens array surface to reduce the reflection from the interface. Moreover, while lens array 300 includes an antireflection film 350 coated on the substrate surface opposing the lens array, in general, lens arrays can include other types of films in addition, or alternatively, to an antireflection film. For example, in some embodiments, lens arrays can include an optical filter (e.g., an absorptive or reflective optical filter) disposed on the substrate surface opposing the lens array. In certain embodiments, lens arrays can include a polarizer (e.g., an absorptive or reflective polarizer) disposed on the substrate surface opposing the lens array.

Referring to FIG. 3B, lenses in lens array 300 are arranged periodically along the x-direction and y-direction. The spatial periods of the lens spacing along the x-axis and y-axis, respectively, are denoted P₃₁₀ₓ and P_{310y}, corresponding to P₁₁₀ₓ and P_{110y} for lens array 100 described above.

As illustrated in FIG. 3B, P₃₁₀ₓ is the same as P_{310y} and the lenses are arranged on a square grid. More generally, however, in embodiments P₃₁₀ₓ can be different from P_{310y}. In other words, lenses 310 can be arranged on a rectangular grid.

Other arrangements are also possible. For example, referring to FIG. 3C, in some embodiments, a lens array 360 can include lenses 361 arranged in a hexagonal pattern.

In some embodiments, different portions of a lens array can be arranged in different patterns. For example, portions of a lens array can be arranged in a square or rectangular pattern, while other portions are arranged in a hexagonal pattern.

In general, lenses in a lens array will adopt the pattern of the underlying pattern of protrusions (e.g., protrusions or ridges), so a desired pattern of lenses can be formed by first forming a corresponding arrangement of protrusions. In general, along one or two directions, lenses can be arranged in a periodic, quasi-periodic (e.g., an arrangement that can be expressed mathematically as the combination of two or more periodic arrangements with incommensurate spatial frequencies), or random pattern. For example, arrays can be arranged in quasi-periodic or random patterns to reduce diffraction of light having wavelengths on the order of the lens size and/or lens spacing.

Furthermore, while the arrays shown in FIGS. 3B and 3C have circular lenses, in general, other lens shapes (such as square shapes or rectangular shapes) are also possible. For example, lenses can be elongated along a particular direction (e.g., along the x-direction or along the y-direction).

Moreover, while the lens arrays shown in FIGS. 3B and 3C are two-dimensional arrays, certain embodiments include one-dimensional lens arrays. For example, referring to FIG. 3D, a lens array 370 includes a one-dimensional array of lenses 371. The lenses are periodically arranged along the x-axis, but extend along the y-direction across the length of lens array 370.

Arrays of lenses can also include lenses of differing size and shape. For example, a lens array can include circular and non-circular (e.g., elliptical) lenses. Alternatively, or additionally, lens arrays can include lenses having different radii of curvature. In some embodiments, lens arrays include lenses with differing lateral dimension. For example, a lens array can include lenses with different lₓ and/or different l_{y}. Lenses in a lens array can have different focal planes and/or different waist sizes.

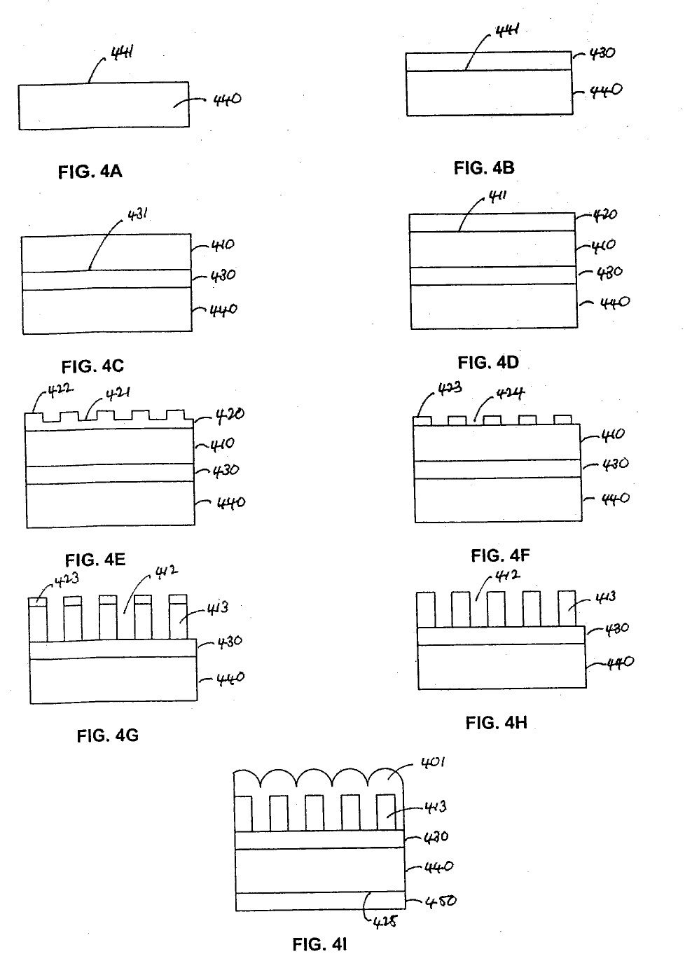

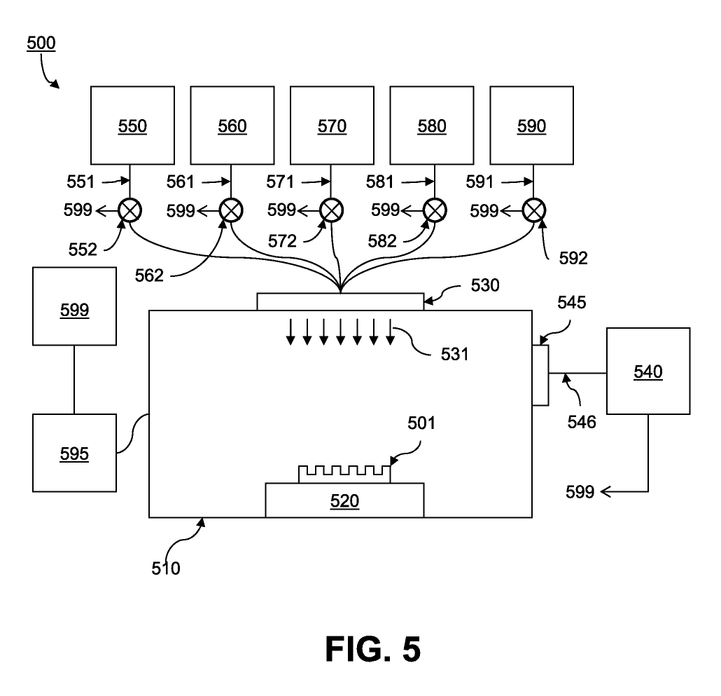

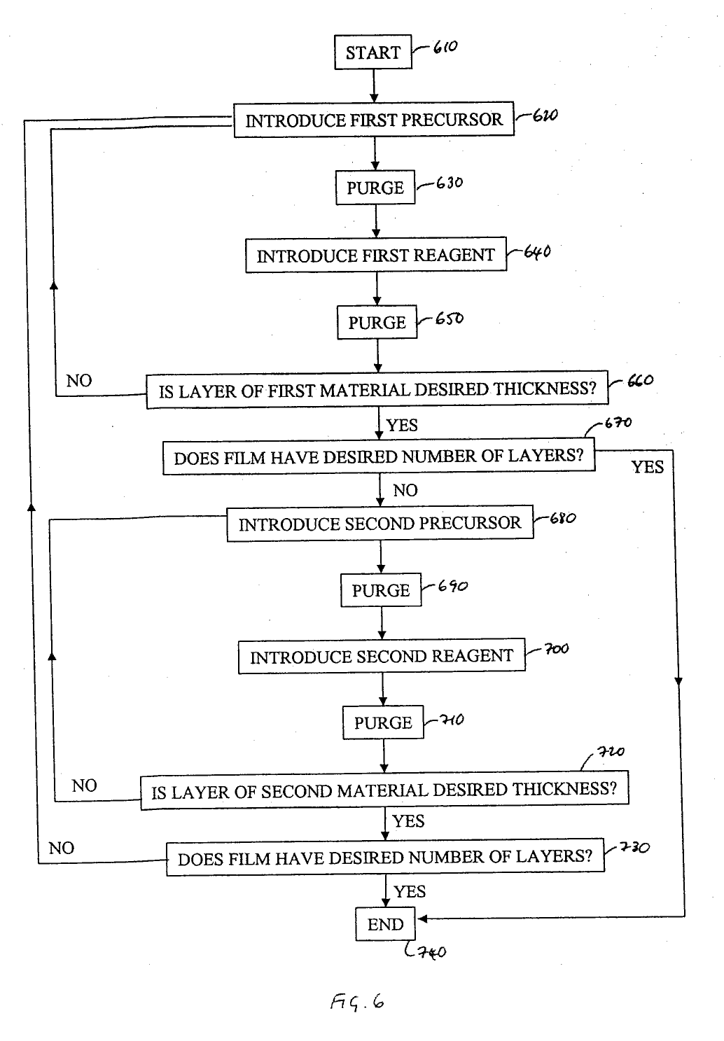

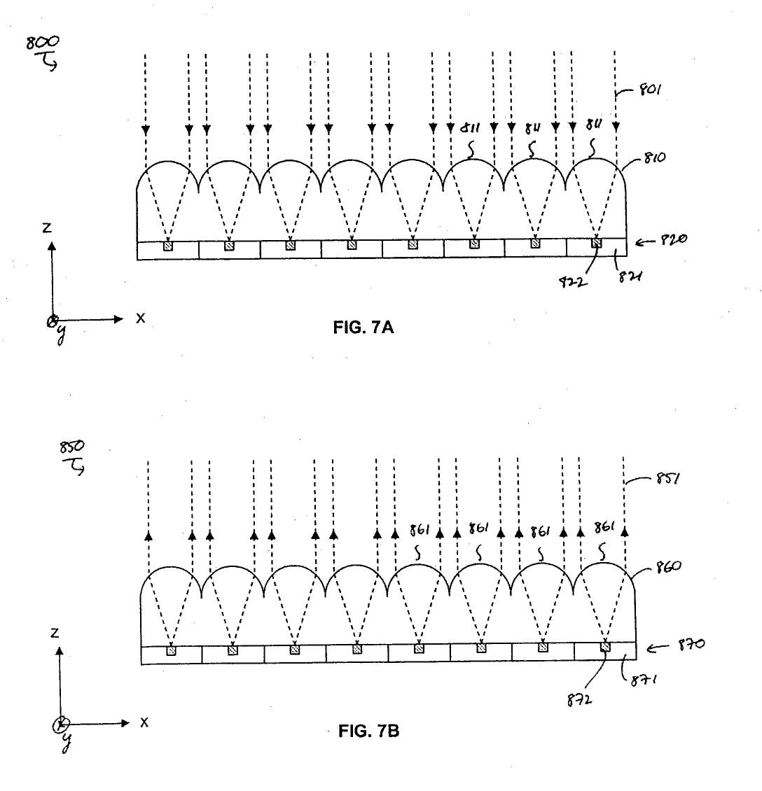

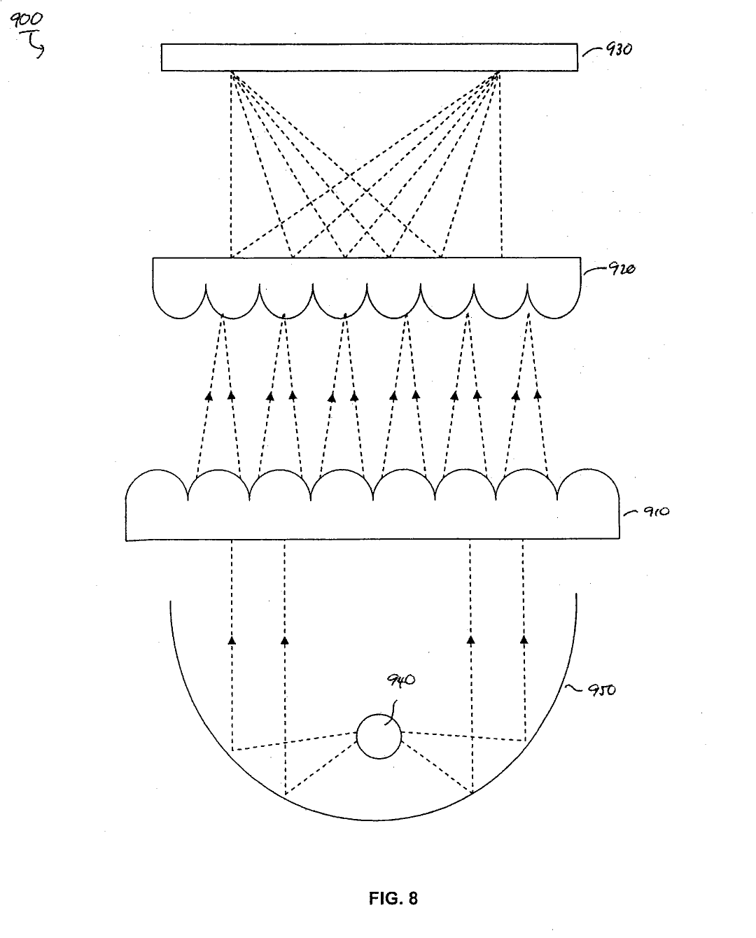

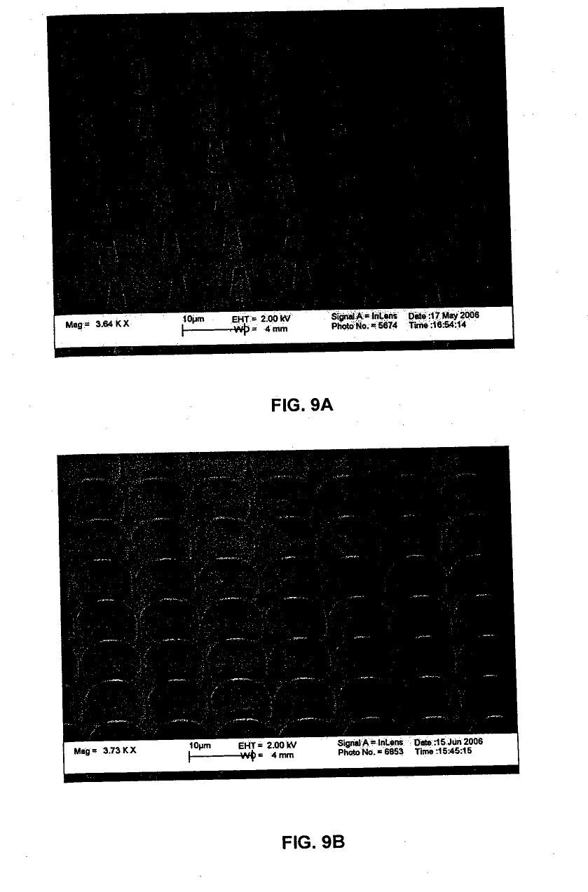

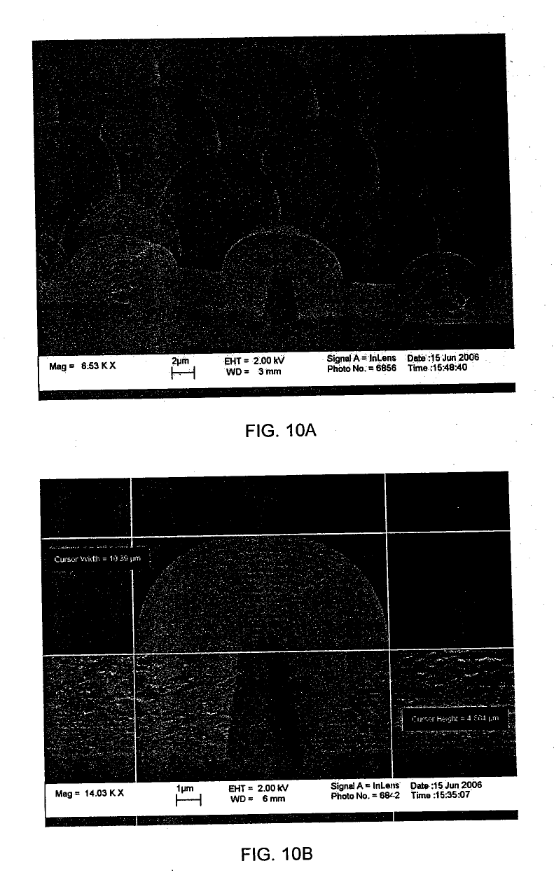

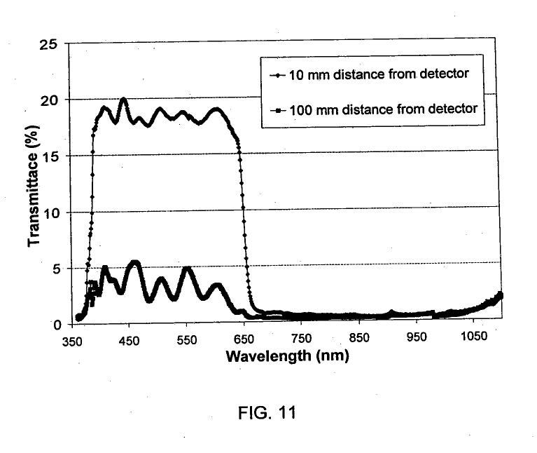

In general, lens arrays can be prepared as desired. FIGS. 4A-4I show different phases of an example of a preparation process. Initially, a substrate 440 is provided, as shown in FIG. 4A. Surface 441 of substrate 440 can be polished and/or cleaned (e.g., by exposing the substrate to one or more solvents, acids, and/or baking the substrate).

Referring to FIG. 4B, etch stop layer 430 is deposited on surface 441 of substrate 440. The material forming etch stop layer 430 can be formed using one of a variety of techniques, including sputtering (e.g., radio frequency sputtering), evaporating (e.g., electron beam evaporation, ion assisted deposition (IAD) electron beam evaporation), or chemical vapor deposition (CVD) such as plasma enhanced CVD (PECVD), atomic layer deposition (ALD), or by oxidization. As an example, a layer of HfO₂ can be deposited on substrate 440 by IAD electron beam evaporation.

Referring to FIG. 4C, an intermediate layer 410 is then deposited on surface 431 of etch stop layer 430. Protrusions are etched from intermediate layer 410, so intermediation layer 410 is formed from the material used for protrusions. The material forming intermediate layer 410 can be deposited using one of a variety of techniques, including sputtering (e.g., radio frequency sputtering), evaporating (e.g., election beam evaporation), or chemical vapor deposition (CVD) (e.g., plasma enhanced CVD). As an example, a layer of SiO₂ can be deposited on etch stop layer 430 by sputtering (e.g., radio frequency sputtering), CVD (e.g., plasma enhanced CVD), or electron beam evaporation (e.g., IAD electron beam deposition). The thickness of intermediate layer 410 is selected based on the desired thickness of the protrusions.

In certain embodiments, intermediate layer 410 is processed to provide protrusions using lithographic techniques. For example, protrusions can be formed from intermediate layer 410 using electron beam lithography or photolithograpy (e.g., using a photomask or using holographic techniques). In some embodiments, protrusions are formed using nano-imprint lithography. Referring to FIG. 4D, nano-imprint lithography includes forming a layer 420 of a resist on surface 411 of intermediate layer 410. The resist can be polymethylmethacrylate (PMMA) or polystyrene (PS), for example. Referring to FIG. 4E, a pattern is impressed into resist layer 420 using a mold. The patterned resist layer 420 includes thin portions 421 and thick portions 422. Patterned resist layer 420 is then etched (e.g., by oxygen reactive ion etching (RIE)), removing thin portions 421 to expose portions 424 of surface 411 of intermediate layer 410, as shown in FIG. 4F. Thick portions 422 are also etched, but are not completely removed. Accordingly, portions 423 of resist remain on surface 411 after etching.

Referring to FIG. 4G, the exposed portions of intermediate layer 410 are subsequently etched, forming gaps 412 in intermediate layer 410. The unetched portions of intermediate layer 410 form protrusions 413. Intermediate layer 410 can be etched using, for example, reactive ion etching, ion beam etching, sputtering etching, chemical assisted ion beam etching (CAIBE), or wet etching. The exposed portions of intermediate layer 410 are etched down to etch stop layer 430, which is formed from a material resistant to the etching method. Accordingly, the depth of gaps 412 formed by etching is the same as the thickness of protrusions 413. After etching gaps 412, residual resist 423 is removed from protrusions 413 as shown in FIG. 4H. Resist can be removed by rinsing the article in a solvent (e.g., an organic solvent, such as acetone or alcohol), by O₂ plasma ashing, O₂ RIE, or ozone cleaning.

Referring to FIG. 4I, after removing residual resist, material is deposited onto the article to form lens layer 401. Material can be deposited onto the protrusions in a variety of ways, including sputtering, electron beam evaporation, CVD (e.g., high density CVD or plasma-enhanced CVD) or atomic layer deposition (ALD), provided the deposited material sufficiently conforms to the protrusions to provide corresponding lenses in the surface of the lens layer.

Finally, antireflection film 450 is deposited onto surface 425 of substrate 440, respectively. Materials forming the antireflection films can be deposited onto the article by sputtering, electron beam evaporation, or ALD, for example.

While certain steps for forming protrusions are described in relation to FIGS. 4A-4I, other steps are also possible. In some embodiments, for example, protrusions are formed directly in a layer of a resist material, rather than in an in a layer that is masked by resist. In certain embodiments, protrusions are embossed directly onto the substrate surface (e.g., of a plastic substrate).

As mentioned previously, in some embodiments, materials forming lens layer 401 and antireflection film 450 are prepared using atomic layer deposition (ALD). Referring to FIG. 5, an ALD system 500 is used to deposit material onto an intermediate article 501 (composed of substrate 440 and protrusions 413) with a homogeneous material or a composite material, such as a nanolaminate multilayer film. Without wishing to be bound by theory, it is believed that deposition using ALD occurs monolayer by monolayer, providing substantial control over the composition and thickness of the films. Furthermore, deposition using ALD can provide a substantially constant deposition rate of material onto exposed surfaces of article 501, regardless of the surface orientation with system 500.

During deposition of a monolayer, vapors of a precursor are introduced into the chamber and are adsorbed onto exposed surfaces of portions 112, etch stop layer surface 131 or previously deposited monolayers adjacent these surfaces. Subsequently, a reactant is introduced into the chamber that reacts chemically with the adsorbed precursor, forming a monolayer of a desired material. The self-limiting nature of the chemical reaction on the surface can provide precise control of film thickness and large-area uniformity of the deposited layer. Moreover, the non-directional adsorption of precursor onto each exposed surface provides for uniform deposition of material onto the exposed surfaces, regardless of the orientation of the surface relative to chamber 510. Accordingly, the layers of the nanolaminate film substantially conform to the shape of the protrusions of intermediate article 301.

ALD system 500 includes a reaction chamber 510, which is connected to sources 550, 560, 570, 580, and 590 via a manifold 530. Sources 550, 560, 570, 580, and 590 are connected to manifold 530 via supply lines 551, 561, 571, 581, and 591, respectively. Valves 552, 562, 572, 582, and 592 regulate the flow of gases from sources 550, 560, 570, 580, and 590, respectively. Sources 550 and 580 contain a first and second precursor, respectively, while sources 560 and 590 include a first reagent and second reagent, respectively. Source 570 contains a carrier gas, which is constantly flowed through chamber 510 during the deposition process transporting precursors and reagents to article 501, while transporting reaction byproducts away from the substrate. Precursors and reagents are introduced into chamber 510 by mixing with the carrier gas in manifold 530. Gases are exhausted from chamber 510 via an exit port 545. A pump 540 exhausts gases from chamber 510 via an exit port 545. Pump 540 is connected to exit port 545 via a tube 546.

ALD system 500 includes a temperature controller 595, which controls the temperature of chamber 510. During deposition, temperature controller 595 elevates the temperature of article 501 above room temperature. In general, the temperature should be sufficiently high to facilitate a rapid reaction between precursors and reagents, but should not damage the substrate. In some embodiments, the temperature of article 501 can be about 500° C. or less (e.g., about 400° C. or less, about 300° C. or less, about 200° C. or less, about 150° C. or less, about 125° C. or less, about 100° C. or less).

Typically, the temperature should not vary significantly between different portions of article 501. Large temperature variations can cause variations in the reaction rate between the precursors and reagents at different portions of the substrate, which can cause variations in the thickness and/or morphology of the deposited layers. In some embodiments, the temperature between different portions of the deposition surfaces can vary by about 40° C. or less (e.g., about 30° C. or less, about 20° C. or less, about 10° C. or less, about 5° C. or less).

Deposition process parameters are controlled and synchronized by an electronic controller 599. Electronic controller 599 is in communication with temperature controller 595; pump 540; and valves 552, 562, 572, 582, and 592. Electronic controller 599 also includes a user interface, from which an operator can set deposition process parameters, monitor the deposition process, and otherwise interact with system 500.

Referring to also FIG. 6, the ALD process is started (610) when system 500 introduces the first precursor from source 550 into chamber 510 by mixing it with carrier gas from source 570 (620). A monolayer of the first precursor is adsorbed onto exposed surfaces of article 501, and residual precursor is purged from chamber 510 by the continuous flow of carrier gas through the chamber (630). Next, the system introduces a first reagent from source 560 into chamber 510 via manifold 530 (640). The first reagent reacts with the monolayer of the first precursor, forming a monolayer of the first material. As for the first precursor, the flow of carrier gas purges residual reagent from the chamber (650). Steps 620 through 660 are repeated until the layer of the first material reaches a desired thickness (660).

In embodiments where the lens layer is formed from a single layer of material, the process ceases once the layer of first material reaches the desired thickness (670). However, for a nanolaminate film, the system introduces a second precursor into chamber 510 through manifold 530 (680). A monolayer of the second precursor is adsorbed onto the exposed surfaces of the deposited layer of first material and carrier gas purges the chamber of residual precursor (690). The system then introduces the second reagent from source 580 into chamber 510 via manifold 530. The second reagent reacts with the monolayer of the second precursor, forming a monolayer of the second material (700). Flow of carrier gas through the chamber purges residual reagent (710). Steps 780 through 710 are repeated until the layer of the second material reaches a desired thickness (720).

Additional layers of the first and second materials are deposited by repeating steps 720 through 730. Once the desired number of layers are formed (e.g., the lenses have the desired shape), the process terminates (740), and the coated article is removed from chamber 510.

While the above-described process and apparatus are discussed in the context of forming a layer of a homogeneous material or a nanolaminate material that includes two different materials, more generally, the process can be used to deposit nanolaminates that include more than two materials. In some embodiments, the process can be used to deposit a layer with a graded index of refraction.

Although the precursor is introduced into the chamber before the reagent during each cycle in the process described above, in other examples the reagent can be introduced before the precursor. The order in which the precursor and reagent are introduced can be selected based on their interactions with the exposed surfaces. For example, where the bonding energy between the precursor and the surface is higher than the bonding energy between the reagent and the surface, the precursor can be introduced before the reagent. Alternatively, if the binding energy of the reagent is higher, the reagent can be introduced before the precursor.

The thickness of each monolayer generally depends on a number of factors. For example, the thickness of each monolayer can depend on the type of material being deposited. Materials composed of larger molecules may result in thicker monolayers compared to materials composed of smaller molecules.

The temperature of the article can also affect the monolayer thickness. For example, for some precursors, a higher temperate can reduce adsorption of a precursor onto a surface during a deposition cycle, resulting in a thinner monolayer than would be formed if the substrate temperature were lower.

The type or precursor and type of reagent, as well as the precursor and reagent dosing can also affect monolayer thickness. In some embodiments, monolayers of a material can be deposited with a particular precursor, but with different reagents, resulting in different monolayer thickness for each combination. Similarly, monolayers of a material formed from different precursors can result in different monolayer thickness for the different precursors.

Examples of other factors which may affect monolayer thickness include purge duration, residence time of the precursor at the coated surface, pressure in the reactor, physical geometry of the reactor, and possible effects from the byproducts on the deposited material. An example of where the byproducts affect the film thickness are where a byproduct etches the deposited material. For example, HCl is a byproduct when depositing TiO₂ using a TiCl₄ precursor and water as a reagent. HCl can etch the deposited TiO₂ before it is exhausted. Etching will reduce the thickness of the deposited monolayer, and can result in a varying monolayer thickness across the substrate if certain portions of the substrate are exposed to HCl longer than other portions (e.g., portions of the substrate closer to the exhaust may be exposed to byproducts longer than portions of the substrate further from the exhaust).

Typically, monolayer thickness is between about 0.1 nm and about five nm. For example, the thickness of one or more of the deposited monolayers can be about 0.2 nm or more (e.g., about 0.3 nm or more, about 0.5 nm or more). In some embodiments, the thickness of one or more of the deposited monolayers can be about three nm or less (e.g., about two nm, about one nm or less, about 0.8 nm or less, about 0.5 nm or less).

The average deposited monolayer thickness may be determined by depositing a preset number of monolayers on a substrate to provide a layer of a material. Subsequently, the thickness of the deposited layer is measured (e.g., by ellipsometry, electron microscopy, or some other method). The average deposited monolayer thickness can then be determined as the measured layer thickness divided by the number of deposition cycles. The average deposited monolayer thickness may correspond to a theoretical monolayer thickness. The theoretical monolayer thickness refers to a characteristic dimension of a molecule composing the monolayer, which can be calculated from the material's bulk density and the molecules molecular weight. For example, an estimate of the monolayer thickness for SiO₂ is ˜0.37 nm. The thickness is estimated as the cube root of a formula unit of amorphous SiO₂ with density of 2.0 grams per cubic centimeter.

In some embodiments, average deposited monolayer thickness can correspond to a fraction of a theoretical monolayer thickness (e.g., about 0.2 of the theoretical monolayer thickness, about 0.3 of the theoretical monolayer thickness, about 0.4 of the theoretical monolayer thickness, about 0.5 of the theoretical monolayer thickness, about 0.6 of the theoretical monolayer thickness, about 0.7 of the theoretical monolayer thickness, about 0.8 of the theoretical monolayer thickness, about 0.9 of the theoretical monolayer thickness). Alternatively, the average deposited monolayer thickness can correspond to more than one theoretical monolayer thickness up to about 30 times the theoretical monolayer thickness (e.g., about twice or more than the theoretical monolayer thickness, about three time or more than the theoretical monolayer thickness, about five times or more than the theoretical monolayer thickness, about eight times or more than the theoretical monolayer thickness, about 10 times or more than the theoretical monolayer thickness, about 20 times or more than the theoretical monolayer thickness).

During the deposition process, the pressure in chamber 510 can be maintained at substantially constant pressure, or can vary. Controlling the flow rate of carrier gas through the chamber generally controls the pressure. In general, the pressure should be sufficiently high to allow the precursor to saturate the surface with chemisorbed species, the reagent to react completely with the surface species left by the precursor and leave behind reactive sites for the next cycle of the precursor. If the chamber pressure is too low, which may occur if the dosing of precursor and/or reagent is too low, and/or if the pump rate is too high, the surfaces may not be saturated by the precursors and the reactions may not be self limited. This can result in an uneven thickness in the deposited layers. Furthermore, the chamber pressure should not be so high as to hinder the removal of the reaction products generated by the reaction of the precursor and reagent. Residual byproducts may interfere with the saturation of the surface when the next dose of precursor is introduced into the chamber. In some embodiments, the chamber pressure is maintained between about 0.01 Torr and about 100 Torr (e.g., between about 0.1 Torr and about 20 Torr, between about 0.5 Torr and 10 Torr, such as about 1 Torr).

Generally, the amount of precursor and/or reagent introduced during each cycle can be selected according to the size of the chamber, the area of the exposed substrate surfaces, and/or the chamber pressure. The amount of precursor and/or reagent introduced during each cycle can be determined empirically.

The amount of precursor and/or reagent introduced during each cycle can be controlled by the timing of the opening and closing of valves 552, 562, 582, and 592. The amount of precursor or reagent introduced corresponds to the amount of time each valve is open each cycle. The valves should open for sufficiently long to introduce enough precursor to provide adequate monolayer coverage of the substrate surfaces. Similarly, the amount of reagent introduced during each cycle should be sufficient to react with substantially all precursor deposited on the exposed surfaces. Introducing more precursor and/or reagent than is necessary can extend the cycle time and/or waste precursor and/or reagent. In some embodiments, the precursor dose corresponds to opening the appropriate valve for between about 0.1 seconds and about five seconds each cycle (e.g., about 0.2 seconds or more, about 0.3 seconds or more, about 0.4 seconds or more, about 0.5 seconds or more, about 0.6 seconds or more, about 0.8 seconds or more, about one second or more). Similarly, the reagent dose can correspond to opening the appropriate valve for between about 0.1 seconds and about five seconds each cycle (e.g., about 0.2 seconds or more, about 0.3 seconds or more, about 0.4 seconds or more, about 0.5 seconds or more, about 0.6 seconds or more, about 0.8 seconds or more, about one second or more)

The time between precursor and reagent doses corresponds to the purge. The duration of each purge should be sufficiently long to remove residual precursor or reagent from the chamber, but if it is longer than this it can increase the cycle time without benefit. The duration of different purges in each cycle can be the same or can vary. In some embodiments, the duration of a purge is about 0.1 seconds or more (e.g., about 0.2 seconds or more, about 0.3 seconds or more, about 0.4 seconds or more, about 0.5 seconds or more, about 0.6 seconds or more, about 0.8 seconds or more, about one second or more, about 1.5 seconds or more, about two seconds or more). Generally, the duration of a purge is about 10 seconds or less (e.g., about eight seconds or less, about five seconds or less, about four seconds or less, about three seconds or less).

The time between introducing successive doses of precursor corresponds to the cycle time. The cycle time can be the same or different for cycles depositing monolayers of different materials. Moreover, the cycle time can be the same or different for cycles depositing monolayers of the same material, but using different precursors and/or different reagents. In some embodiments, the cycle time can be about 20 seconds or less (e.g., about 15 seconds or less, about 12 seconds or less, about 10 seconds or less, about 8 seconds or less, about 7 seconds or less, about 6 seconds or less, about 5 seconds or less, about 4 seconds or less, about 3 seconds or less). Reducing the cycle time can reduce the time of the deposition process.

The precursors are generally selected to be compatible with the ALD process, and to provide the desired deposition materials upon reaction with a reagent. In addition, the precursors and materials should be compatible with the material on which they are deposited (e.g., with the substrate material or the material forming the previously deposited layer). Examples of precursors include chlorides (e.g., metal chlorides), such as TiCl₄, SiCl₄, SiH₂Cl₂, TaCl₃, HfCl₄, InCl₃ and AlCl₃. In some embodiments, organic compounds can be used as a precursor (e.g., Ti-ethaOxide, Ta-ethaOxide, Nb-ethaOxide). Another example of an organic compound precursor is (CH₃)₃Al.

The reagents are also generally selected to be compatible with the ALD process, and are selected based on the chemistry of the precursor and material. For example, where the material is an oxide, the reagent can be an oxidizing agent. Examples of suitable oxidizing agents include water, hydrogen peroxide, oxygen, ozone, (CH₃)₃Al, and various alcohols (e.g., Ethyl alcohol CH₃OH). Water, for example, is a suitable reagent for oxidizing precursors such as TiCl₄ to obtain TiO₂, AlCl₃ to obtain Al₂O₃, and Ta-ethaoxide to obtain Ta₂O₅, Nb-ethaoxide to obtain Nb₂O₅, HfCl₄ to obtain HfO₂, ZrCl₄ to obtain ZrO₂, and InCl₃ to obtain In₂O₃. In each case, HCl is produced as a byproduct. In some embodiments, (CH₃)₃Al can be used to oxidize silanol to provide SiO₂.

Lens arrays can be used in a variety of applications. For example, referring to FIG. 7A, a lens array 810 forms part of a detector array 800. Lens array 810 includes lenses 811, each of which correspond to a detector element 821. Detector elements 821 each include a light sensitive element 822, positioned at or near the focal plane of the corresponding lens. Each lens 811 focuses light 801 incident on the lens element propagating parallel to the z-axis onto the light sensitive element 822 of the detector element corresponding to lens element 811.

In some embodiments, detector elements 821 are complementary metal-oxide-semiconductor (CMOS) or charged couple device (CCD) detector elements.

While only eight detector elements are shown in FIG. 7A, in general, the number of detector elements in a detector array can vary. Moreover, while detector array is shown in cross-section and shows the elements arrayed in one dimension only, detector array 800 can be a two dimensional array. Embodiments of detector arrays can include about 10⁶ or more detector elements (e.g., about 2×10⁶ or more, about 3×10⁶ or more, about 4×10⁶ or more, about 5×10⁶ or more, about 6×10⁶ or more, about 7×10⁶ or more, about 8×10⁶ or more).

Embodiments of detector arrays can include additional components to those shown in FIG. 7A. For example, in some embodiments, detector array 800 can include color filters corresponding to each detector element. For example, detector array 800 can include an array of red, green, and blue color filters, each transmitting only red, green, or blue light to the respective detector element. In another example, detector array 800 can include an array of cyan, magenta, and yellow color filters.

Using lens arrays to focus light onto light sensitive elements 822 can improve the collection efficiency of the detector array. Collection efficiency refers to the percentage of light intensity at λ that is incident on lenses 811 and is incident on light sensitive elements 822.

In some embodiments, detector array 800 has a collection efficiency of about 50% or more (e.g., about 60% or more, about 70% or more, about 80% or more, about 90% or more, about 95% or more) or more at λ.

Detector arrays with higher collection efficiencies are typically more sensitive (e.g., provide higher signal to noise ratios) than comparable detector arrays that do not utilize lens arrays.

Detector arrays, such as detector array 800, can be used in a variety of applications. In some embodiments, detector arrays are used in digital cameras, such as digital cameras for cellular telephones. Detector arrays can also be used in measurement tools, such as spectrophotometers, for example. In some embodiments, detector arrays are used in telecommunication systems. For example, detector arrays can be used in detection modules for fiber optic communication systems.

Referring to FIG. 7B, in some embodiments, a lens array 860 is used in an emissive device, such as in flat panel display 850. In addition to lens array 860, flat panel display 850 includes an array 870 of emissive pixels 871. Each emissive pixel 861 includes an emissive element 862 which during operation emits light at a desired wavelength.

Each lens 861 of lens array 860 corresponds to a respective pixel 871. During operation, light 851 emitted from the corresponding pixel is collimated by the corresponding lens 861 of lens array 860, exiting display 800 propagating parallel to the z-axis. In this way, lens array 860 provides greater directionality to light emitted by display 850 compared to similar displays that don't include lens arrays.

In both detector array 800 and flat panel display 850, respective lens arrays 810 and 860 can be integrated onto the detector/pixel array during fabrication of the device.

In some applications, lens arrays can be used to homogenize radiation from a light source. For example, referring to FIG. 8, two lens arrays 910 and 920 are used in an optical system 900 to homogenize radiation from a light source 940 directed to a target 930. Light emitted (e.g., isotropically) from source 940 is directed by a reflector 950 to first lens array 910, which focuses paraxial radiation onto second lens array 920. Second lens array 920 directs the radiation to target 930, distributing it in a homogeneous manner (e.g., so that the radiation has a substantially constant intensity at each position on target 930) thereon.

In some embodiments, lens arrays can be used in illumination systems for providing homogenous, collimated light to a target. For example, lens arrays can be used in projection displays (e.g., a rear projection display or a front projection display) to provide collimated illumination to light modulator (e.g., a poly-silicon LC light valve or a digital micromirror device). In some embodiments, a first lens array can be used to focus light from a source to an entrance aperture of projection optics of the projection display, while a second lens array collimates the focused light before it illuminates the light modulator.

Still further applications of lens arrays include as components of telecommunications systems, such as for coupling radiation into optical fibers and/or collimating light that exits optical fibers.

### EXAMPLES

### Example 1

### Lens Array with Homogenous ALD Deposition

A lens array was prepared using a fused silica substrate having a thickness of 0.5 mm. The substrate had a diameter of 100 mm. The substrates were procured from Ohara Corporation (Branchburg, N.J.). First, an array of protrusions having a conical shape was formed in a surface of the substrate as follows. A 160 nm thick Cr layer was deposited by e-beam deposition on the fused silica substrate. A layer of AZ1809 photoresist (procured from Clariant Corporation, Fair Lawn, N.J.), approximately 500 nm thick, was deposited on the surface of the Cr layer using a spin coater. The resist layer was baked at 80° C. for about 1 min and then exposed to patterned radiation using an mask aligner (from AB-M, Inc., San Jose, Calif.) with a photomask made by Photronics, Inc. (Brookfield, Conn.). The photomask was a bright field photomask having a periodic dot pattern with dot diameters of 2 μm and a pitch of 10 μm. The exposed resist layer was developed using AZ300 developer (obtained from Brewer Science, Inc., Rolla, Mo.) by immersing the exposed resist in the developer, yielding a patterned resist layer. The substrate surface was then etched through the patterned resist layer using CR-7, obtained from Cyantek Corporation (Fremont, Calif.).

The etched Cr layer consisted of Cr dots with various diameters between 300 nm to ˜1.5 μm. Reactive ion etching (RIE) was then used to etch the fused silica using the Cr dots as etch mask. The fused silica was etched to a depth of approximately 5 μm. Finally, the Cr mask was removed by CR-7.

After etching, the substrate surface consisted of a two-dimensional an array of conical protrusions arranged in a square pattern. An scanning electron micrograph of the array is shown in FIG. 9A. FIG. 9A shows a perspective view of a portion of the seed array at a magnification of 3,640×. The array had a period of approximately 10 microns along both dimensions. The conical protrusions had a base width of approximately 2.5 microns and a peak width of approximately 1.5 microns. The protrusions had a height of approximately 5 microns.

Atomic layer deposition was used to form a film of SiO₂ over the substrate surface as follows. To deposit the film, the etched substrate was placed in a P400A ALD reaction chamber, obtained from Planar Systems, Inc. (Beaverton, Oreg.). Prior to deposition, the substrate was heated to 300° C. inside the ALD chamber for about three hours. The chamber was flushed with nitrogen gas, flowed at about 2 SLM, maintaining the chamber pressure at about 0.75 Torr. The SiO₂ precursor was silanol (tris(tert-butoxy)silanol), pre-heated to about 110° C. The precursor was 99.999% grade purity, obtained from Sigma-Aldrich (St. Louis, Mo.). The reagent used was water, which was maintained at about 13° C. SiO₂ monolayers were deposited by introducing water to the ALD chamber for one second, followed by a two second nitrogen purge. Silanol was then introduced for one second. The chamber was then purged for three seconds with nitrogen before the next pulse of reagent. This process was repeated until the SiO₂ layer was approximately 4.8 μm thick.

Referring to FIG. 9B, the resulting structure was studied using scanning electron microscopy. FIG. 9B shows a perspective view of a portion of the lens array at a magnification of 3,730×. The microlens array is composed of approximately spherical lenses with diameters of approximately 10 microns and base-to-vertex height of approximately 5 microns.

### Example 2

### Lens Array with Multilayer ALD Deposition

A two-dimensional array of conical protrusions was formed as described in Example 1. Atomic layer deposition onto this seed layer was used to form a multilayer film over the substrate surface as follows.

The high index material was TiO₂ and the low index material was SiO₂. The precursor for the high index material was Ti-ethaoxide, 99.999% grade purity, obtained from Sigma-Aldrich (St. Louis, Mo.). The Ti-ethaoxide was pre-heated to about 150° C. The precursor for the low index material was silanol (tris(tert-butoxy)silanol), also 99.999% grade purity, obtained from Sigma-Aldrich (St. Louis, Mo.). The silanol (tris(tert-butoxy)silanol) was pre-heated to about 120° C. For both materials, the reagent was deionized water, which was provided using a water deionizer obtained from Allied Water Technologies (Danbury, Conn.) and maintained at about 13° C.

To deposit the multilayer film, the etched substrate was placed in a P400A ALD reaction chamber, obtained from Planar Systems, Inc. (Beaverton, Oreg.). Air was purged from the chamber. Nitrogen was flowed through the chamber, maintaining the chamber pressure at about 1 Torr. The chamber temperature was set to 170° C. and left for about seven hours for the substrate to thermally equilibrate. Once thermal equilibrium was reached, alternating layers of TiO₂ and SiO₂ were deposited on the substrate as follows.

An initial pulse of water vapor was introduced into the chamber by opening the valve to the water supply for one second. After the valve to the water supply was closed, the chamber was purged by the nitrogen flow for two seconds. Next, the valve to the Ti-ethaoxide was opened for one second, introducing Ti-ethaoxide into the chamber. The chamber was again allowed to purge by the nitrogen flow for two seconds before another dose of water vapor was introduced. Alternating doses of water vapor and Ti-ethaoxide were introduced between purges, resulting in a layer of TiO₂ being formed on the exposed surfaces of the substrate. This cycle was repeated several times, the exact number depending on the desired layer thickness according to Table I.

A similar process was used to form the SiO₂ layers. An initial pulse of water vapor was introduced into the chamber by opening the valve to the water supply for one second. After the valve to the water supply was closed, the chamber was purged by the nitrogen flow for two seconds. Next, the valve to the Silanol was opened for one second, introducing the SiO2 reagent into the chamber. The chamber was again allowed to purge by the nitrogen flow for three seconds before another dose of water vapor was introduced. Alternating doses of water vapor and Silanol were introduced between purges, resulting in a layer of SiO₂ being formed on the exposed surfaces. This cycle was repeated several times, the exact number depending on the desired layer thickness according to Table I.]

TABLE I
Target layer thickness for multilayer
film deposited on seed structure.

| Layer | TiO₂ Layer | SiO₂ Layer |
|---|---|---|
| No. | (nm) | (nm) |
| 1 | 12.77 | 30.91 |
| 2 | 36.15 | 1.56 |
| 3 | 86.38 | 18.1 |
| 4 | 38.07 | 15.07 |
| 5 | 144.29 | 4.24 |
| 6 | 147.92 | 4.18 |
| 7 | 144.49 | 5.91 |
| 8 | 138.16 | 10.96 |
| 9 | 122.23 | 49.92 |
| 10 | 12.5 | 57.41 |
| 11 | 96.44 | 54.94 |
| 12 | 8.3 | 58.09 |
| 13 | 100.29 | 34.96 |
| 14 | 18.98 | 29.61 |
| 15 | 99.9 | 50.14 |
| 16 | 12.44 | 55.85 |
| 17 | 96.14 | 81.15 |
| 18 | 0 | 64.77 |
| 19 | 83.43 | 138.39 |
| 20 | 79.71 | 47.08 |
| 21 | 0 | 88.14 |
| 22 | 78.07 | 42.87 |
| 23 | 0.09 | 91.16 |
| 24 | 79.48 | 139.93 |
| 25 | 100.37 | 42.33 |
| 26 | 21.48 | 61.65 |
| 27 | 21.16 | 43.19 |
| 28 | 101.5 | 141.26 |
| 29 | 85.38 | 69.07 |
| 30 | 0.78 | 74.71 |
| 31 | 18.62 | 13.5 |
| 32 | 132.57 | 29.95 |
| 33 | 7.88 | 114.61 |
| 34 | 94.65 | 118.88 |
| 35 | 7.93 | 31.79 |
| 36 | 130.39 | 24.03 |
| 37 | 9.93 | 62.47 |
| 38 | 0 | 72.91 |
| 39 | 95.73 | 111.09 |
| 40 | 6.79 | 38.76 |
| 41 | 131.54 | 29.5 |
| 42 | 19.44 | 71.07 |
| 43 | 14.45 | 23.93 |
| 44 | 82.52 | 74.16 |

Referring to FIGS. 10A and 10B, the resulting structure was studied using scanning electron microscopy. FIG. 10A show a perspective view of a portion of the lens array at a magnification of about 6,500×. FIG. 10B shows a cross-sectional view of a lens at a magnification of about 14,000×. The microlens array is composed of approximately spherical, hexagonally close-packed lenses with diameters of approximately 10 microns and base-to-vertex height of approximately 5 microns.

Referring to FIG. 11, the performance of the optical filter was investigated using a Lambda 14 UV/V is spectrometer, obtained from Perkin-Elmer (Wellesley, Mass.). The transmission spectrum of the lens array was measured at 0° incidence with the detector positioned approximately 10 mm and approximately 100 mm from the lens array. At 0°, the pass band extended from about 380 nm to about 650 nm. Based on the measurement made with the detector approximately 100 mm from the lens array, transmission at these wavelengths was between about 17% and 20%. The lens array substantially blocked light at wavelengths from about 670 nm to about 1,100 nm.

Other embodiments are in the following claims.

1. A method, comprising
providing an article having a surface comprising a plurality of protrusions; and using atomic layer deposition to deposit a layer of a first material on the surface of the article to form a plurality of lenses, each lens corresponding to a protrusion on the article surface, and each lens having a surface formed using atomic layer deposition.

2. The method of claim 1 wherein depositing the first material comprises sequentially depositing a plurality of layers of the first material where one of the layers of the first material is deposited on the surface of the article.

3. The method of claim 2 wherein depositing the plurality of layers of the first material comprises depositing a layer of a precursor and exposing the layer of the precursor to a reagent to provide a layer of the first material.

4. The method of claim 3 wherein the reagent chemically reacts with the precursor to form the first material.

5. The method of claim 4 wherein the reagent oxidizes the precursor to form the first material.

6. The method of claim 3 wherein depositing the layer of the precursor comprises introducing a first gas comprising the precursor into a chamber housing the article.

7. The method of claim 6 wherein exposing the layer of the precursor to the reagent comprises introducing a second gas comprising the reagent into the chamber.

8. The method of claim 7 wherein a third gas is introduced into the chamber after the first gas is introduced and prior to introducing the second gas.

9. The method of claim 8 wherein the third gas is inert with respect to the precursor.

10. The method of claim 8 wherein the third gas comprises at least one gas selected from the group consisting of helium, argon, nitrogen, neon, krypton, and xenon.

11. The method of claim 2 wherein the precursor is selected from the group consisting of tris(tert-butoxy)silanol, (CH₃)₃Al, TiCl₄, SiCl₄, SiH₂Cl₂, TaCl₃, AlCl₃, Hf-ethoxide and Ta-ethoxide.

12. The method of claim 2 wherein forming the layer comprising the first material further comprises depositing a second material by sequentially depositing a plurality of layers of the second material, one of the layers of the second material being deposited on the first material, wherein the second material is different from the first material.

13. The method of claim 2 wherein the plurality of layers of the first material are monolayers of the first material.

14-16. (canceled)

17. The method of claim 1 wherein the first material is a dielectric material.

18. The method of claim 1 wherein the first material is an oxide.

19. The article of claim 18 wherein the oxide is selected from the group consisting of SiO₂, Al₂O₃, Nb₂O₅, TiO₂, ZrO₂, HfO₂ and Ta₂O₅.

20. The method of claim 1 wherein the layer comprising the first material is formed by depositing one or more additional materials on the article, where the one or more additional materials are different from the first material.

21. The method of claim 1 wherein the layer comprising the first material is formed from a nanolaminate material that includes the first material.

22. The method of claim 1 wherein the protrusions are formed in a layer comprising a substrate material, where the first material and the substrate material are the same.

23. The method of claim 1 wherein the protrusions are formed from a second material, where the first material and the second material are different.

24. The method of claim 1 further comprising forming the protrusions in a surface of the article prior to depositing the first material.

25. The method of claim 24 wherein the article comprises a substrate material and forming the protrusions comprises etching the substrate material.

26. The method of claim 24 wherein the article comprises a substrate and forming the protrusions comprises depositing a layer of a second material on a surface of a substrate.

27. The method of claim 24 wherein forming the protrusions comprises forming a layer of a resist on a base layer and transferring a pattern to the layer of the resist, where the pattern corresponds to an arrangement of the protrusions.

28. The method of claim 27 wherein the pattern is transferred to the resist using a lithographic technique.

29. The method of claim 28 wherein the pattern is transferred to the resist using photolithography.

30. The method of claim 28 wherein the pattern is transferred to the resist using imprint lithography.

31. The method of claim 1 wherein the protrusions are periodically arranged on the article surface.

32. The method of claim 31 wherein the arrangement of protrusions has a period of about 1 μm or more in at least one direction.

33. The method of claim 31 wherein the arrangement of protrusions has a period of about 3 μm or more in at least one direction.

34. The method of claim 31 wherein the arrangement of protrusions has a period of about 30 μm or less in at least one direction.

35. The method of claim 31 wherein the arrangement of protrusions has a period of about 20 μm or less in at least one direction.

36. The method of claim 1 wherein at least some of the plurality of lenses have a radius of curvature in a first plane of about 20 μm or less.

37. The method of claim 1 wherein at least some of the plurality of lenses have a radius of curvature in a first plane of about 10 μm or less.

38. The method of claim 1 wherein at least two of the lenses are different sizes.

39. The method of claim 1 wherein each of the lenses in the plurality of lenses is substantially the same size as the other lenses in the plurality of lenses.

40. The method of claim 1 wherein the plurality of lenses form a lens array.

41. The method of claim 1 wherein the lenses are cylindrical lenses.

42. The method of claim 1 wherein the protrusions are ridges that extend along a first direction in a plane of the article.

43. The method of claim 1 wherein the protrusions are conical protrusions.

44-88. (canceled)

89. A method comprising:
forming a plurality of lenses on a substrate, wherein forming the plurality of lenses consists of:
providing an article having a surface comprising a plurality of protrusions; and
using atomic layer deposition to deposit one or more layers on the surface of the article to form the plurality of lenses, each lens corresponding to a protrusion on the article's surface.
